(19) United States
(12) Patent Application Publication
(10) Pub. No.: US 2026/0304000 A1
(43) Pub. Date: Oct. 1, 2026

(54) PHOTOELECTRIC CONVERSION APPARATUS AND EQUIPMENT

(71) Applicant: CANON KABUSHIKI KAISHA, Tokyo (JP)

(72) Inventor: Daisuke Kobayashi, Kanagawa (JP)

(21) Appl. No.: 19/568,960

(22) Filed: Mar. 17, 2026

(30) Foreign Application Priority Data
Mar. 27, 2025 (JP) 2025-053749

(51) Int. Cl. H04N 25/771; H10F 39/00

(52) U.S. Cl. CPC H04N 25/771; H10F 39/8037

(57) ABSTRACT

A photoelectric conversion apparatus including a first amplifier output a signal obtained by amplifying a signal from a photoelectric convertor to a node, a transistor connecting a capacitor to the node, and a second amplifier amplifying a signal of the node is provided. The first and second amplifier operate when a first signal is at a first voltage and do not operate at a second voltage, the transistor is turned on when a second signal is at a third voltage and is turned off at a fourth voltage. In a driving mode, a first time of the second signal transiting from the fourth voltage to the third voltage and/or a second time of transiting from the third voltage to the fourth voltage is longer than a third time of the first signal transiting between the first and second voltages.

### BACKGROUND

### Field of the Technology

The present disclosure relates to a photoelectric conversion apparatus and equipment.

### Description of the Related Art

There has been proposed performing a global electronic shutter operation in a photoelectric conversion apparatus, in which reset of photoelectric conversion elements arranged in a plurality of pixels and readout of a charge from the conversion elements are simultaneously performed. Japanese Patent Laid-Open No. 2022-051548 shows an image sensor having a voltage holding type global electronic shutter function of converting a signal charge into a voltage and holding it.

To improve the quality of an image generated in a photoelectric conversion apparatus, it is necessary to suppress noise that is generated in a pixel circuit.

### SUMMARY

Some embodiments of the present disclosure provide a technique advantageous in reducing noise.

According to some embodiments, a photoelectric conversion apparatus which includes a plurality of pixels each having a photoelectric conversion element arranged therein, comprising: a first amplification circuit configured to output, to a second node, a first signal obtained by amplifying a signal level of a first node to which a signal is supplied from the photoelectric conversion element; a holding capacitor; a first transistor arranged between the second node and the holding capacitor; a second amplification circuit configured to output a second signal obtained by amplifying a signal level of the second node; and a processing circuit configured to process the second signal, wherein the first amplification circuit and the second amplification circuit are configured to be set in an operation state when a first control signal is at a first voltage, and to be set in a nonoperation state when the first control signal is at a second voltage, the first transistor is configured to be set in an ON state when a second control signal is at a third voltage, and to be set in an OFF state when the second control signal is at a fourth voltage, and the photoelectric conversion apparatus is configured to be able to operate in a driving mode in which at least one of a first transition time of the second control signal transiting from the fourth voltage to the third voltage and a second transition time of transiting from the third voltage to the fourth voltage is longer than a third transition time of the first control signal transiting between the first voltage and the second voltage, is provided.

Features of the present disclosure will become apparent from the following description of embodiments with reference to the attached drawings. The following description of embodiments is described by way of example.

### BRIEF DESCRIPTION OF THE DRAWINGS

FIG. 1 is a view showing an example of the configuration of a photoelectric conversion apparatus according to the embodiment;

FIG. 2 is a view showing an example of the configuration of the photoelectric conversion apparatus shown in FIG. 1;

FIG. 3 is a view showing an example of the configurations of the pixel, the pixel memory, and the processing circuit of the photoelectric conversion apparatus shown in FIG. 1;

FIGS. 4A and 4B are views showing an example of the configurations of the current sources of the photoelectric conversion apparatus shown in FIG. 1;

FIG. 5 is a view showing an example of the configuration of the vertical scanning circuit of the photoelectric conversion apparatus shown in FIG. 1;

FIG. 6 is a view showing an example of the arrangement of the vertical scanning circuit and the control wirings of the photoelectric conversion apparatus shown in FIG. 1;

FIG. 7 is a view showing an example of the arrangement of the vertical scanning circuit and the control wirings of the photoelectric conversion apparatus shown in FIG. 1;

FIG. 8 is a view showing an example of the arrangement of the vertical scanning circuit and the control wirings of the photoelectric conversion apparatus shown in FIG. 1;

FIG. 9 is a view showing an example of the configuration of the driver of the photoelectric conversion apparatus shown in FIG. 1;

FIG. 10 is a view showing an example of the configuration of the driver of the photoelectric conversion apparatus shown in FIG. 1;

FIG. 11 is a view showing an example of the configuration of the driver of the photoelectric conversion apparatus shown in FIG. 1;

FIG. 12 is a view showing an example of the configuration of the driver of the photoelectric conversion apparatus shown in FIG. 1;

FIG. 13 is a view showing an example of the configuration of the driver of the photoelectric conversion apparatus shown in FIG. 1;

FIG. 14 is a timing chart showing an example of the operation of the photoelectric conversion apparatus shown in FIG. 1;

FIG. 15 is a view for explaining the relationship between pixel data and the waveform of a control signal of the photoelectric conversion apparatus shown in FIG. 1;

FIG. 16 is a view for explaining the relationship between pixel data and the waveform of a control signal of the photoelectric conversion apparatus shown in FIG. 1;

FIG. 17 is a view for explaining the distribution of pixel data when light enters the photoelectric conversion apparatus shown in FIG. 1;

FIG. 18 is a view for explaining the relationship between pixel data and the waveform of a control signal of the photoelectric conversion apparatus shown in FIG. 1;

FIG. 19 is a view for explaining the relationship between pixel data and the waveform of a control signal of the photoelectric conversion apparatus shown in FIG. 1;

FIG. 20 is a timing chart showing an example of the operation of the photoelectric conversion apparatus shown in FIG. 1;

FIG. 21 is a timing chart showing an example of the operation of the photoelectric conversion apparatus shown in FIG. 1;

FIG. 22 is a timing chart showing an example of the operation of the photoelectric conversion apparatus shown in FIG. 1;

FIG. 23 is a timing chart showing an example of the operation of the photoelectric conversion apparatus shown in FIG. 1;

FIG. 24 is a view showing an example of the arrangement of the signal generator of the photoelectric conversion apparatus shown in FIG. 1;

FIG. 25 is a view for explaining the relationship between pixel data and the waveform of a control signal of the photoelectric conversion apparatus shown in FIG. 1;

FIG. 26 is a view for explaining the relationship between pixel data and the waveform of a control signal of the photoelectric conversion apparatus shown in FIG. 1;

FIG. 27 is a view showing an example of the arrangement of the signal generator of the photoelectric conversion apparatus shown in FIG. 1;

FIG. 28 is a view showing an example of the arrangement of the signal generator of the photoelectric conversion apparatus shown in FIG. 1;

FIG. 29 is a view showing an example of the arrangement of the signal generator of the photoelectric conversion apparatus shown in FIG. 1;

FIG. 30 is a view showing an example of the arrangement of the buffer of the photoelectric conversion apparatus shown in FIG. 1;

FIG. 31 is a view showing an example of the arrangement of the buffer of the photoelectric conversion apparatus shown in FIG. 1;

FIG. 32 is a view showing an example of the configuration of the pixel memory of the photoelectric conversion apparatus shown in FIG. 1;

FIG. 33 is a timing chart showing an example of the operation of the photoelectric conversion apparatus shown in FIG. 1;

FIG. 34 is a view showing an example of the configuration of the pixel memory of the photoelectric conversion apparatus shown in FIG. 1; and

FIG. 35 is a view showing an example of the configuration of equipment incorporating the photoelectric conversion apparatus according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the following description, terms (for example, "upper", "lower", "right", "left" and other terms including these terms) representing specific directions or positions are used, as necessary. These terms are used for easy understanding of the embodiments with reference to the accompanying drawings, and the meanings of the terms do not limit the technical scope of the present disclosure.

In this specification, a planar view is viewing from a direction perpendicular to the light incident surface of a semiconductor layer. A sectional view indicates a plane in the direction perpendicular to the light incident surface of the semiconductor layer. Note that if the light incident surface of the semiconductor layer is rough microscopically, the planar view is defined with reference to the light incident surface of the semiconductor layer when viewed macroscopically.

In this specification, if a term "impurity concentration" is simply used, this means a net impurity concentration obtained by subtracting an impurity concentration compensated by impurities of an opposite conductivity type. That is, the "impurity concentration" indicates a NET doping concentration. A region where the concentration of added p-type impurities is higher than the concentration of added n-type impurities is a p-type semiconductor region. To the contrary, a region where the concentration of added n-type impurities is higher than the concentration of added p-type impurities is an n-type semiconductor region.

In the following embodiment, connection between elements of a circuit may be described. In this case, even if another element is interposed between elements of interest, the elements of interest are handled as connected unless it is specifically stated otherwise. For example, assume that an element A is connected to one node of a capacitive element C having a plurality of nodes, and an element B is connected to another node. Even in this case, the elements A and B are handled as connected unless it is specifically stated otherwise.

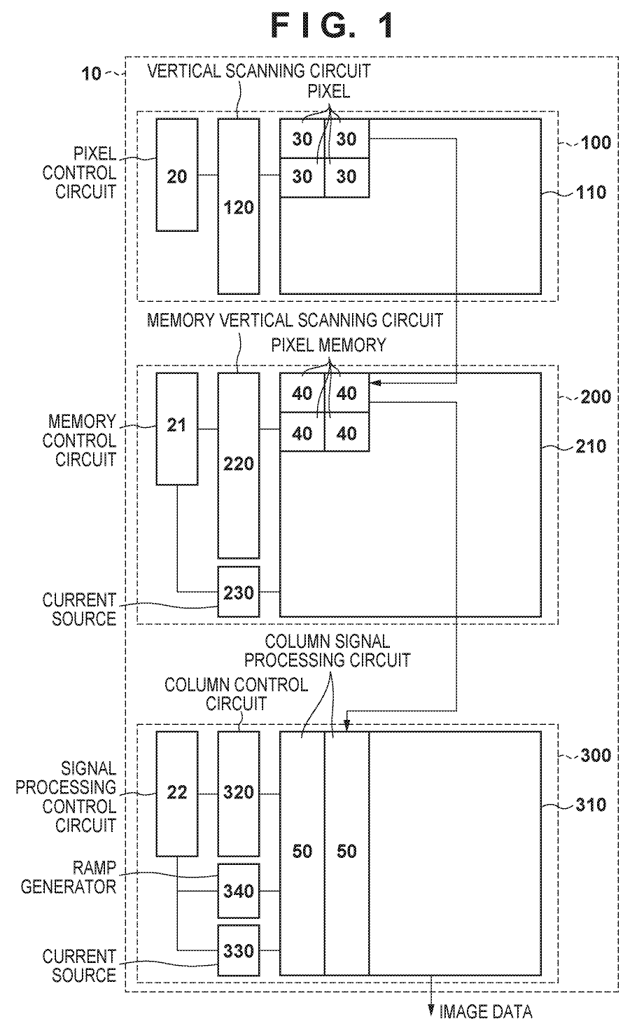

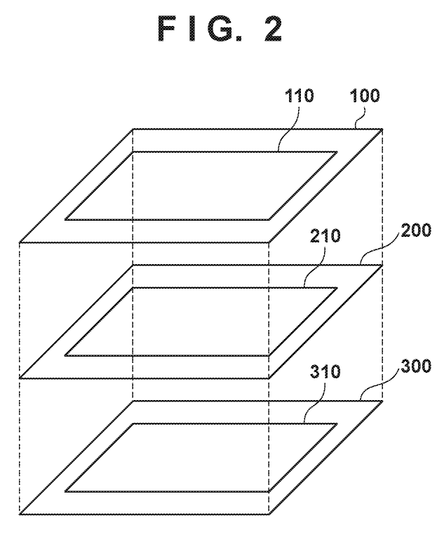

The embodiment according to the present disclosure will be described with reference to FIGS. 1 to 34. FIG. 1 is a schematic view showing an example of the configuration of a photoelectric conversion apparatus 10 according to this embodiment. As shown in FIG. 2, the photoelectric conversion apparatus 10 is formed by stacking a substrate 100 on which a plurality of pixels 30 each including a photoelectric conversion element are arranged, a substrate 200 on which a plurality of pixel memories 40 are arranged, and a substrate 300 on which processing circuits (column signal processing circuits 50) configured to process signals output from the pixels are arranged. Wiring patterns provided on the substrates 100, 200, and 300 are connected, thereby exchanging signals between the substrates 100, 200, and 300. The substrates 100, 200, and 300 can each also be called a chip.

The substrate 100 shown in FIG. 1 includes a pixel region 110, a vertical scanning circuit 120, and a pixel control circuit 20. The pixel region 110 is a region in which the pixels 30 that are unit pixels are arranged in an array to form a plurality of rows and a plurality of columns. The pixel 30 includes a photoelectric conversion element such as a photodiode, and outputs a signal voltage according to an incident light amount. In the pixel region 110, not only effective pixels each configured to output a pixel signal according to the amount of incident light but also optical black pixels whose photoelectric conversion elements are shielded from light or dummy pixels that do not output a signal may be arranged. The number of rows and the number of columns of the pixels 30 arranged in the pixel region 110 are not particularly limited. The pixel control circuit 20 is a logic circuit that generates timing to operate the pixels 30, and outputs a driving pulse for the pixels 30 to the vertical scanning circuit 120. The vertical scanning circuit 120 includes a driver that drives the pixels 30 in each row or in a plurality of rows. The driver provided in the vertical scanning circuit 120 is a signal generation circuit that generates a control signal for operating the pixels 30. Also, the vertical scanning circuit 120 including the driver is a part of a signal generator that generates a control signal for operating the photoelectric conversion apparatus 10.

The substrate 200 includes a memory region 210, a memory vertical scanning circuit 220, a current source 230, and a memory control circuit 21. The memory region 210 is a region in which the pixel memories 40 are arranged in an array to form a plurality of rows and a plurality of columns. The pixel memory 40 has a function of holding a signal voltage output from the pixel 30. In FIG. 1, one pixel 30 and one pixel memory 40 are arranged in correspondence with each other, but the pixels 30 and the pixel memories 40 need not be arranged in a one-to-one correspondence. For example, the pixel memory 40 may not be arranged in correspondence with a dummy pixel that does not output a signal. Alternatively, a dummy pixel memory that does not output a signal may be arranged in correspondence with a dummy pixel. The current source 230 supplies a reference current to the pixel memories 40. The memory control circuit 21 includes a logic circuit that generates timing to operate the pixel memories 40 or controls circuits such as the current source 230 arranged around the pixels. A driving pulse output from the memory control circuit 21 is input to the memory vertical scanning circuit 220. The memory vertical scanning circuit 220 includes a driver that drives the pixel memories 40 in each row. The driver provided in the memory vertical scanning circuit 220 is a signal generation circuit that generates a control signal for operating the pixel memories 40. Also, the memory vertical scanning circuit 220 including the driver is a part of a signal generator that generates a control signal for operating the photoelectric conversion apparatus 10.

The substrate 300 includes a signal processor 310, a column control circuit 320, a ramp generator 340, a current source 330, and a signal processing control circuit 22. In the signal processor 310, the column signal processing circuits 50 are arranged in an array to form a plurality of columns. The column signal processing circuit 50 has a function of analog/digital (A/D) converting a signal voltage output from the pixel memory 40 based on a reference voltage generated by the ramp generator 340, and outputs the digital signal after conversion as image data to the outside of the photoelectric conversion apparatus 10. In this embodiment, ramp-type A/D conversion will be described as an example. However, the method of A/D conversion is not limited to the ramp type, and performing A/D conversion of an appropriate method suffices. Also, the column signal processing circuit 50 may have a function of performing digital processing such as noise processing for image data. The current source 330 supplies a reference current to the column signal processing circuits 50. The signal processing control circuit 22 includes a logic circuit that generates timing to operate the column signal processing circuits 50 or performs function settings for the ramp generator 340 and the current source 330. A driving pulse output from the signal processing control circuit 22 is input to the column control circuit 320. The column control circuit 320 includes a driver that outputs the driving pulse to the column signal processing circuits 50. The driver provided in the column control circuit 320 is a signal generation circuit that generates a control signal for operating the column signal processing circuits 50. Also, the column control circuit 320 including the driver is a part of a signal generator that generates a control signal for operating the photoelectric conversion apparatus 10.

The substrates 100, 200, and 300 are stacked as shown in FIG. 2, thereby forming the photoelectric conversion apparatus 10. The substrate 100 can also be referred to as a pixel chip; the substrate 200, a memory chip; and the substrate 300, a signal processing chip. In accordance with the flow of a signal, the substrate 200 with the pixel memories 40 arranged thereon can be arranged between the substrate 100 with the pixels 30 arranged thereon and the substrate 300 with the column signal processing circuits 50 arranged thereon.

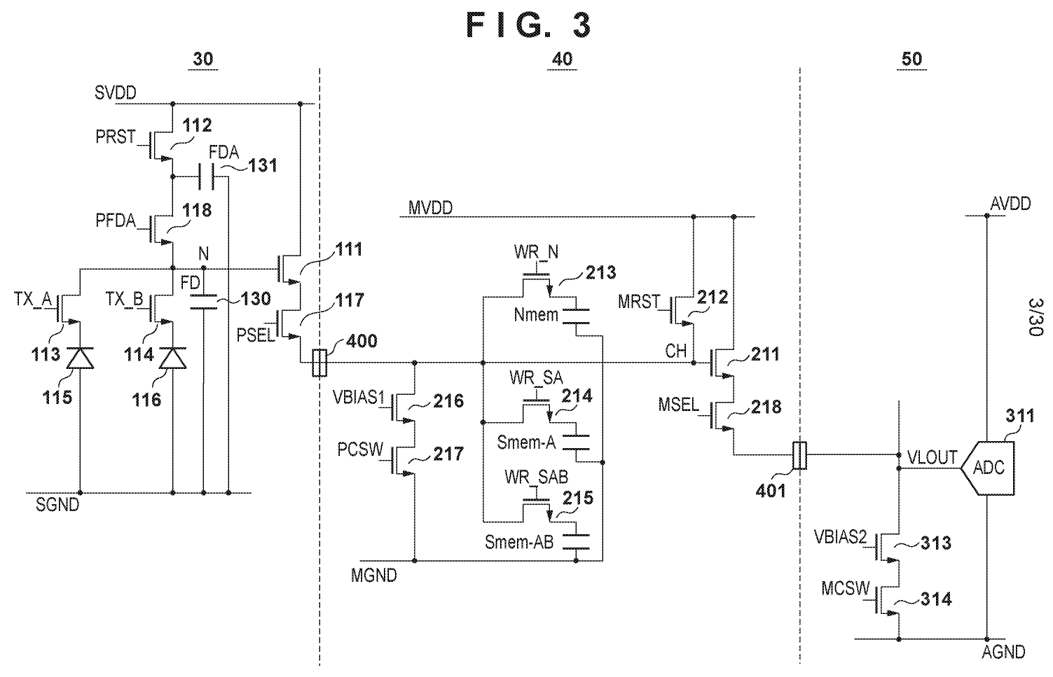

The photoelectric conversion apparatus 10 according to this embodiment can be a photoelectric conversion apparatus that performs a so-called voltage domain type global shutter operation. Signal readout from the pixel 30 in the photoelectric conversion apparatus 10 according to this embodiment will be described with reference to FIGS. 3 to 14.

FIG. 3 is a view showing an example of the configurations of the pixel 30, the pixel memory 40, and the column signal processing circuit 50 for reading out a signal from one pixel 30. The pixel 30 includes photodiodes (PDs) 115 and 116 that are photoelectric conversion elements, a pixel transfer transistor 113, a pixel transfer transistor 114, a floating diffusion (FD) capacitor 130, and a pixel reset transistor 112. Also, the pixel 30 includes a capacitor selection transistor 118 and an additional capacitor (FDA capacitor) 131. The pixel 30 further includes a pixel amplification transistor 111 and a pixel selection transistor 117.

In this embodiment, the photoelectric conversion apparatus 10 is a photoelectric conversion apparatus having a so-called Phase Detection Auto Focus (PDAF) function, in which the PD 115 and the PD 116 are arranged in one pixel 30, and signals of the PD 115 and the PD 116 are used for phase difference detection. However, the configuration is not limited to this. Only one of the PD 115 and the PD 116 may be arranged. The anode terminal of the PD 115 is connected to a reference power supply SGND, and the cathode terminal is connected to the source of the pixel transfer transistor 113. The anode terminal of the PD 116 is connected to the reference power supply SGND, and the cathode terminal is connected to the source of the pixel transfer transistor 114. The drain of the pixel transfer transistor 113 and the drain of the pixel transfer transistor 114 are connected to the gate of the pixel amplification transistor 111 and the source of the capacitor selection transistor 118, respectively. The drain of the capacitor selection transistor 118 is connected to the FDA capacitor 131 and the source of the pixel reset transistor 112. The FD capacitor 130 is connected to the gate of the pixel amplification transistor 111 using the reference power supply SGND as a reference, and a signal charge generated by the PD 115 and the PD 116 can be held. In addition, the FDA capacitor 131 is connected to the PD 115 and the PD 116 via the capacitor selection transistor 118 using the reference power supply SGND as a reference, thereby holding the signal charge generated by these. Thus, as for holding of the signal charge generated by the PD 115 and the PD 116, only the FD capacitor 130 or the FD capacitor 130 and the FDA capacitor 131 can be selected, and it is possible to adjust the signal charge amount to be held. The drains of the pixel reset transistor 112 and the pixel amplification transistor 111 are connected to a reference power supply SVDD. The source of the pixel amplification transistor 111 is connected to the drain of the pixel selection transistor 117. The transistors arranged in the pixel 30 may be n-type transistors, as shown in FIG. 3, or some or all of these may be p-type transistors.

An example of the configuration of the pixel memory 40 will be described next. The pixel memory 40 includes a signal holding memory Nmem, a signal holding memory Smem-A, and a signal holding memory Smem-AB. The plurality of signal holding memories will sometimes be referred to together as a signal holding memory mem hereinafter. The signal holding memory mem is a holding capacitor that holds a voltage signal according to the signal level of a signal output from the pixel. A memory write transistor 213 is arranged between the signal holding memory Nmem and a node CH to which the voltage signal according to the signal output from the pixel is supplied. A memory write transistor 214 is arranged between the signal holding memory Smem-A and the node CH. A memory write transistor 215 is arranged between the signal holding memory Smem-AB and the node CH. The pixel memory 40 is configured to further include a memory reset transistor 212, a memory amplification transistor 211, a current source transistor 216, a switch transistor 217, and a memory selection transistor 218. The transistors arranged in the pixel memory 40 may be n-type transistors, as shown in FIG. 3, or some or all of these may be p-type transistors.

The source of the pixel selection transistor 117 of the pixel 30 is connected to the drain of the current source transistor 216 of the pixel memory 40 via a joint portion 400. The source of the current source transistor 216 is connected to the drain of the switch transistor 217. VBIAS1 is supplied from the current source 230 to the gate of the current source transistor 216, and control is performed such that a current based on VBIAS1 flows. The configuration of the current source 230 will be described later.

The signal holding memory Nmem has one terminal connected to a power supply wiring for supplying a reference power supply MGND and the other terminal connected to the source of the memory write transistor 213. The drain of the memory write transistor 213 is connected to the gate of the memory amplification transistor 211. Similarly, the signal holding memory Smem-A has one terminal connected to the power supply wiring for supplying the reference power supply MGND and the other terminal connected to the source of the memory write transistor 214. The drain of the memory write transistor 214 is connected to the gate of the memory amplification transistor 211. The signal holding memory Smem-AB has one terminal connected to the power supply wiring for supplying the reference power supply MGND and the other terminal connected to the source of the memory write transistor 215. The drain of the memory write transistor 215 is connected to the gate of the memory amplification transistor 211. The signal holding memory mem need only be an element having a function of holding a signal. The signal holding memory mem may be, for example, a DRAM, an MIM capacitor, or a diffusion capacitor formed by a diffusion layer on Si and polysilicon.

An example of the configuration of the column signal processing circuit 50 will be described next. The column signal processing circuit 50 is configured to include an A/D converter (ADC) 311, a current source transistor 313, and a switch transistor 314. The source of the current source transistor 313 is connected to the drain of the switch transistor 314, and the source of the switch transistor 314 is connected to a power supply wiring for supplying a reference power supply AGND. VBIAS2 is supplied from the current source 330 to the gate of the current source transistor 313, and a current based on VBIAS2 flows to the current source transistor 313. The drain of the current source transistor 313 is connected to the input of the ADC 311 via a signal line VLOUT, and the ADC 311 is connected to a power supply wiring for supplying a reference power supply AVDD and the power supply wiring for supplying the reference power supply AGND. As shown in FIG. 3, the current source transistor 313 and the switch transistor 314 can be n-type transistors or p-type transistors.

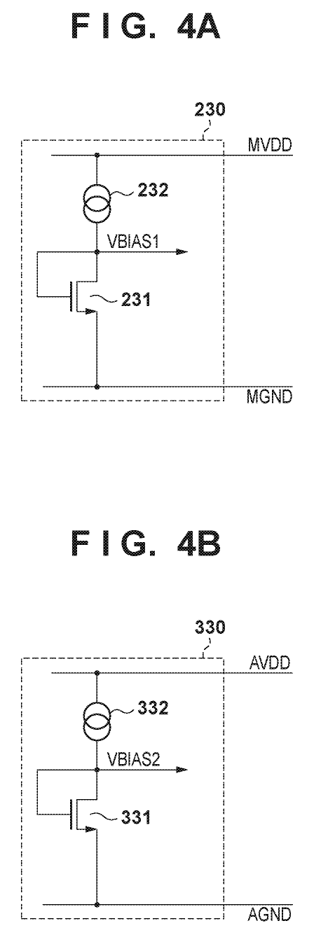

Here, examples of the configurations of the current source 230 and the current source 330 are shown in FIGS. 4A and 4B. In the current source 230, a current mirror is formed by a reference current source 232 and a bias generation transistor 231. The reference current source 232 that generates a reference current is connected between a power supply wiring for supplying a reference power supply MVDD and the drain of the bias generation transistor 231. The source of the bias generation transistor 231 is connected to the power supply wiring for supplying the reference power supply MGND. VBIAS1 generated by connecting the gate of the bias generation transistor 231 to the drain of the bias generation transistor 231 is supplied to each pixel memory 40. In the current source 330, a current mirror is formed by a reference current source 332 and a bias generation transistor 331. The reference current source 332 that generates a reference current is connected between the power supply wiring for supplying the reference power supply AVDD and the drain of the bias generation transistor 331. The source of the bias generation transistor 331 is connected to the power supply wiring for supplying the reference power supply AGND. VBIAS2 generated by connecting the gate of the bias generation transistor 331 to the drain of the bias generation transistor 331 is supplied to each column signal processing circuit 50.

In this embodiment, the joint portion 400 shown in FIG. 3 indicates the joint portion when bonding the substrate 100 and the substrate 200. Also, the joint portion 401 indicates the joint portion when bonding the substrate 200 and the substrate 300. The substrate 100 and the substrate 200 are electrically connected by the joint portion 400, and the substrate 200 and the substrate 300 are electrically connected by the joint portion 401. The joint portions 400 and 401 can be formed by, for example, Cu to Cu Bonding (CCB), Through Silicon Via (TSV), and the like. Here, the connection relationship of the above-described reference power supplies is not limited to the configuration described in this embodiment. For example, the reference power supply SGND and the reference power supply MGND may be a (same) common reference power supply, and the reference power supply MGND and the reference power supply AGND may be a (same) common reference power supply. Also, the substrates to arrange the control circuits, the scanning circuits, and the current sources are not limited to the configurations described in this embodiment. For example, the memory control circuit 21 and the current source 230 arranged on the substrate 200 may be arranged on the substrate 300, and the current source 330 may be commonly used on the substrate 200 and the substrate 300. Furthermore, the functions of the substrate 200 and the substrate 300 may be implemented by one substrate (chip), and the photoelectric conversion apparatus 10 may have a configuration formed by stacking the substrate 100 and one substrate having the functions of the substrate 200 and the substrate 300.

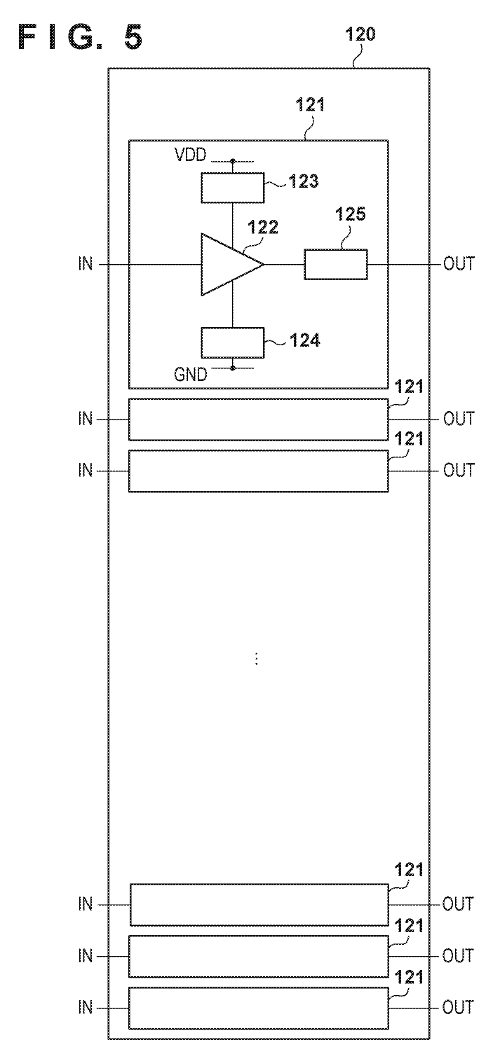

The configuration of a driver 121 that forms the vertical scanning circuit 120 shown in FIG. 1 will be described next. FIG. 5 is a view for explaining the configuration of the vertical scanning circuit 120. The vertical scanning circuit 120 is configured to include a plurality of drivers 121 in accordance with a plurality of control signals for driving the transistors arranged in the pixels 30 or units of a single row to be driven or units of a plurality of rows to be driven. Defining an input signal as IN and an output signal as OUT, the driver 121 is formed by a buffer portion 122 and waveform controllers 123 to 125. Here, a reference power supply VDD is connected to the waveform controller 123, and a reference power supply GND is connected to the waveform controller 124. However, for example, the reference power supplies SVDD and SGND or the reference power supplies MVDD and MGND shown in FIG. 3 may be connected. In FIG. 5, the plurality of drivers 121 are arranged one by one in the row direction (vertical direction), but a plurality of drivers may be parallelly arranged in each row or in a plurality of rows. In the plurality of drivers 121 shown in FIG. 5, the input signal IN and the output signal OUT are indicated by the same reference symbols. However, the input signals IN and the output signals OUT of the drivers 121 may be different control signals, or may be controlled at different timings.

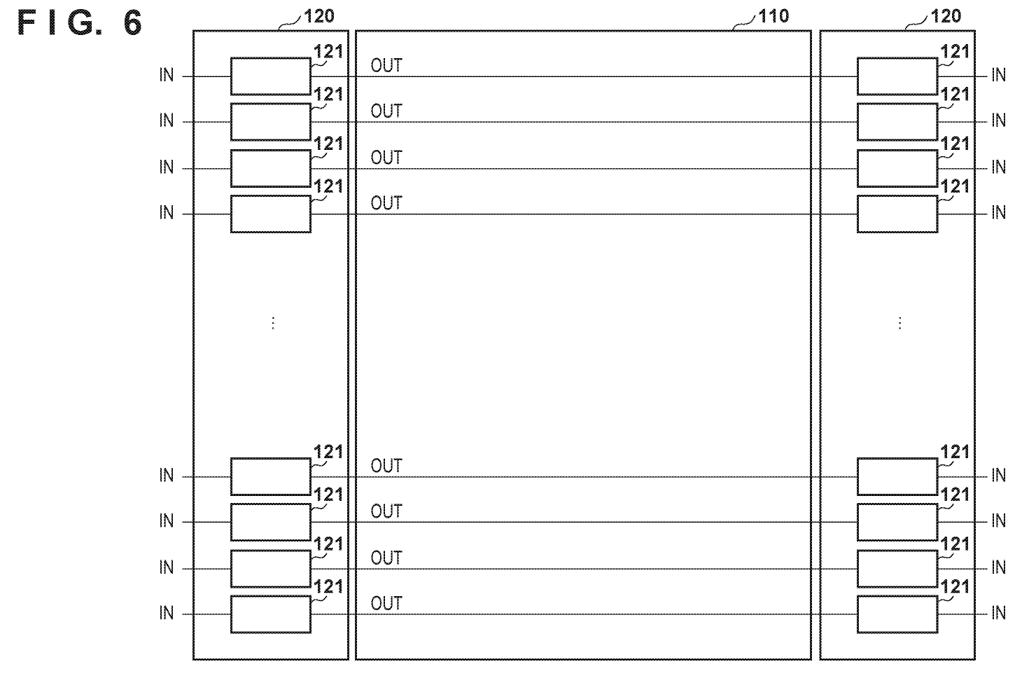

FIG. 6 shows a configuration example in which the vertical scanning circuits 120 are arranged on the left and right sides with respect to the pixel region 110. If the output signals OUT of the drivers 121 are the same control signal on the left and right sides, these may be short-circuited as shown in FIG. 6. With this configuration, the drivers 121 provided in the vertical scanning circuit 120 forming a part of the signal generator can control, among the plurality of pixels 30, the pixels 30 arranged in one row via a common control signal line. However, the present disclosure is not limited to this and even if the same control signal is supplied, the output signals may not be short-circuited as shown in FIG. 6. In this case, control signal lines for supplying different control signals from the drivers 121 on the left and right sides may be arranged.

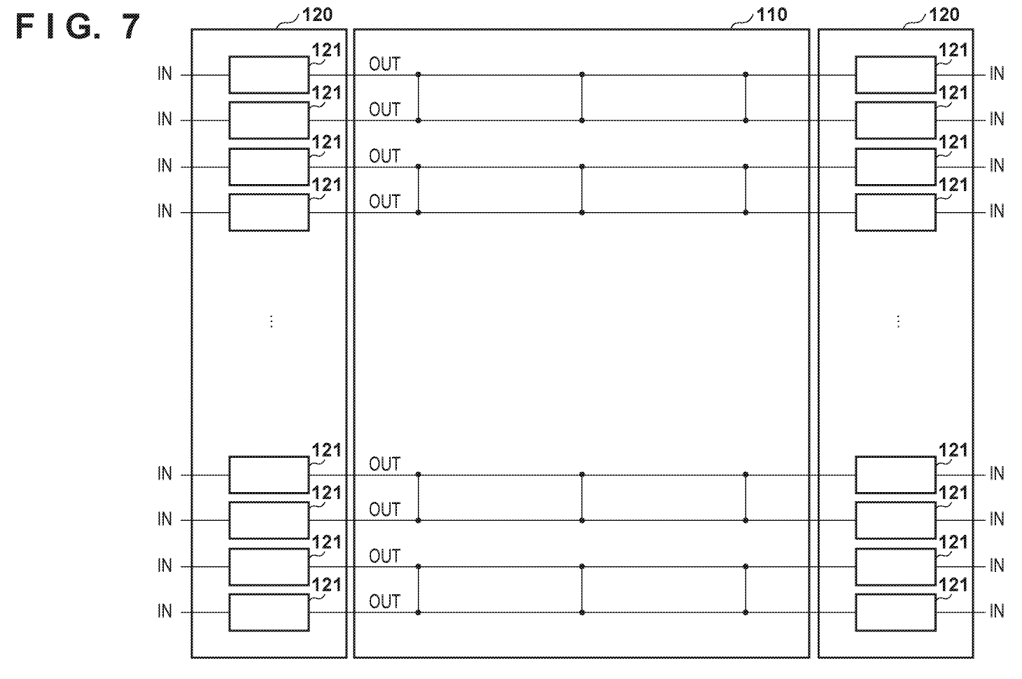

FIG. 7 is a view showing a modification of the configuration shown in FIG. 6. In the configuration shown in FIG. 7, the vertical scanning circuits 120 are arranged on the left and right sides with respect to the pixel region 110, and the output signals OUT of the drivers 121 are short-circuited on the left and right sides. Furthermore, the output signals OUT of the drivers 121 adjacent to each other in the column direction (up/down direction) are short-circuited. As a result, the drivers 121 control, among the plurality of pixels, the pixels 30 arranged in two or more rows via a common control signal line. By short-circuiting the output signals OUT of the drivers 121 adjacent in the column direction, for example, when controlling the pixels 30 in units of a plurality of rows, the operation timings of the plurality of pixels 30 to be controlled simultaneously can be synchronized. In addition, it is possible to reduce the wiring parasitic resistance of the control signal line for supplying the output signal OUT of the driver 121 in the pixel region 110 and thus improve the quality of the waveform of the control signal by reducing the delay amount of the control signal. FIG. 7 shows an example in which the output signals OUT of the drivers 121 adjacent to each other in the column direction are short-circuited, but the output signals OUT of the drivers 121 may be short-circuited in units of a plurality of rows including three or more rows as a unit of the pixels 30 to be controlled similarly. Also, for example, the output signals OUT of the drivers 121 that are not adjacent to each other may be short-circuited. It suffices that depending on the configuration of the transistors arranged in the pixel 30 or the configuration of the vertical scanning circuit 120, the output signals OUT of the drivers 121 are short-circuited in an appropriate combination.

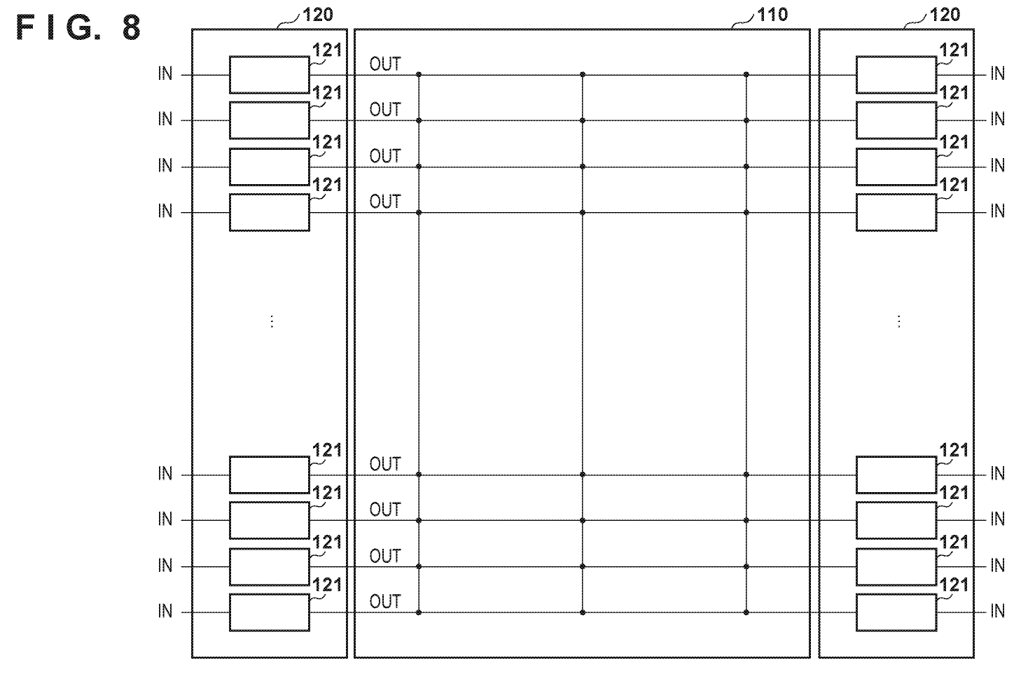

FIG. 8 is a view showing a modification of the configurations shown in FIGS. 6 and 7. In the configuration shown in FIG. 8, the vertical scanning circuits 120 are arranged on the left and right sides with respect to the pixel region 110, and the output signals OUT of the drivers 121 are short-circuited on the left and right sides. Furthermore, the output signals OUT of all drivers 121 in the column direction, which supply the same control signal, are short-circuited. Thus, for example, all output signals OUT supplied to transistors and the like operating at the same timing in the constituent elements arranged in the pixels 30 are short-circuited. The configuration shown in FIG. 8 can synchronize the operation timings of the pixels 30 in a case where the same control is performed for all pixels 30. In addition, like the configuration shown in FIG. 7, it is possible to reduce the wiring parasitic resistance of the control signal line for supplying the output signal OUT of the driver 121 in the pixel region 110 and thus improve the quality of the waveform of the control signal. The wiring pattern that short-circuits the output signals OUT of the drivers 121 in the column direction shown in FIGS. 7 and 8 may be formed in units of a single column of the pixels 30 or in units of a plurality of columns.

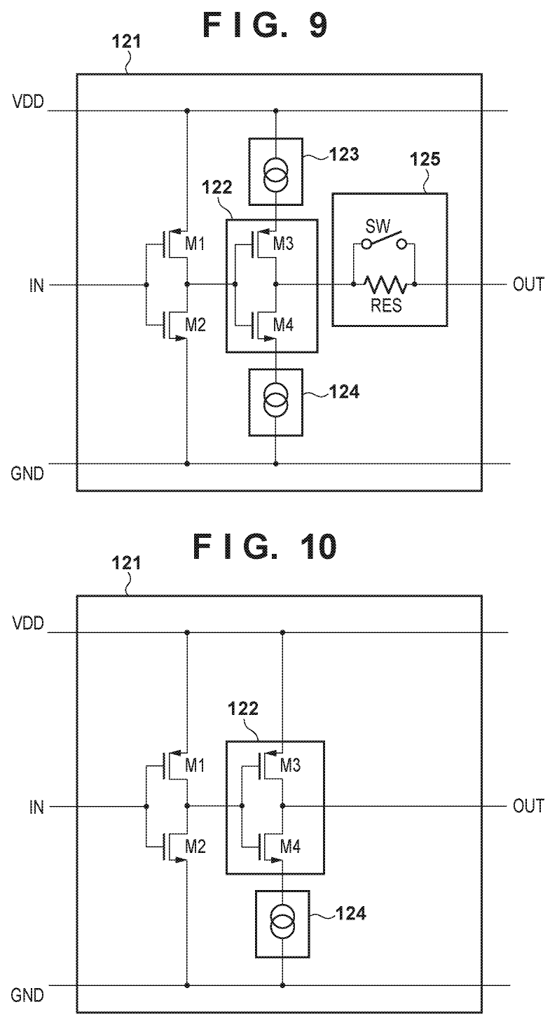

FIG. 9 is a view showing a detailed example of the configuration of the driver 121. The input signal IN is input to an inverter circuit formed by a p-type transistor M1 and an n-type transistor M2. The output of the inverter circuit is input to a buffer portion 122 formed by a p-type transistor M3 and an n-type transistor M4. The waveform controller 123 is connected to the reference power supply VDD and the source of the p-type transistor M3. The waveform controller 124 is connected to the reference power supply GND and the source of the n-type transistor M4. The waveform controller 125 is connected to the output of the buffer portion 122, and the output of the buffer portion 122 is the output signal OUT of the driver 121.

The driver 121 shown in FIG. 9 is configured to be able to variably control the transition times of rising and falling of the output signal OUT using the waveform controllers 123 and 124 as variable current sources. When the output signal OUT transitions from low to high, that is, when transition from the voltage of the reference power supply GND to the voltage of the reference power supply VDD occurs, the transition time is decided by the current of the waveform controller 123 and a load connected to the output signal OUT, for example, a control signal line for supplying a control signal or the gate load of a transistor in the pixel 30 to which the control signal is supplied. That is, the transition time of rising of the output signal OUT of the driver 121 can variably be controlled by the waveform controller 123. When the output signal OUT transitions from high to low, that is, when transition from the voltage of the reference power supply VDD to the voltage of the reference power supply GND occurs, the transition time is decided by the current of the waveform controller 124 and a load connected to the output signal OUT, for example, a control signal line for supplying a control signal or the gate load of a transistor in the pixel 30 to which the control signal is supplied. That is, the transition time of falling of the output signal OUT of the driver 121 can variably be controlled by the waveform controller 124.

The waveform controller 125 is configured to include a switch SW and a variable resistive element RES. If the switch SW is ON, the output signal OUT is controlled by the waveform controllers 123 and 124. If the switch SW is OFF, the transition time of the output signal OUT is decided not only by control of the transition time by the waveform controllers 123 and 124 but also by a time constant decided by the variable resistive element RES and a load, for example, a control signal line for supplying a control signal or the gate load of a transistor in the pixel 30 to which the control signal is supplied. That is, the transition times of rising and falling of the output signal OUT of the driver 121 can variably be controlled by the waveform controller 125. The switch SW may be turned on or off at one of the rising and falling of the output signal OUT. For the waveform controllers 123 and 124 as well, a disable or enable state and the transition time can be controlled by a switch (not shown) or current control of a variable current source.

FIGS. 10 to 13 show modifications of the driver 121 shown in FIG. 9, and show configuration examples in which the arrangement configuration of the waveform controllers 123 to 125 is changed in accordance with the control signal. FIG. 10 shows an example in which only the waveform controller 124 is arranged, and the waveform controllers 123 and 125 are not arranged. In the configuration shown in FIG. 10, only the transition time of the output signal OUT of the driver 121 from high to low, that is, falling is controlled.

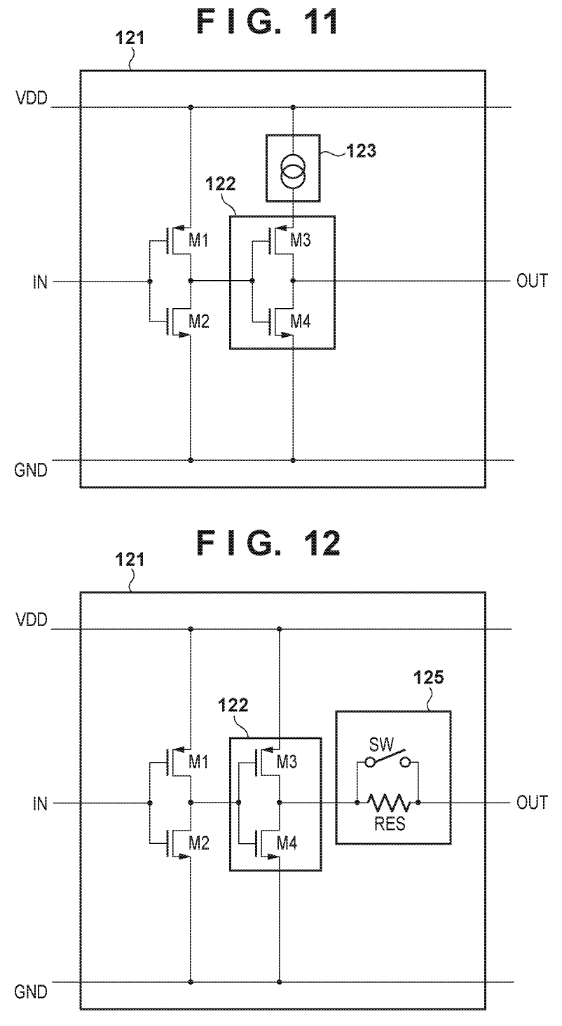

FIG. 11 shows an example in which only the waveform controller 123 is arranged, and the waveform controllers 124 and 125 are not arranged. In the configuration shown in FIG. 11, only the transition time of the output signal OUT of the driver 121 from low to high, that is, rising is controlled.

FIG. 12 shows an example in which only the waveform controller 125 is arranged, and the waveform controllers 123 and 124 are not arranged. The transition times of rising and falling of the output signal OUT of the driver 121 are controlled by the time constant decided by the variable resistive element RES and a load connected to the output signal OUT.

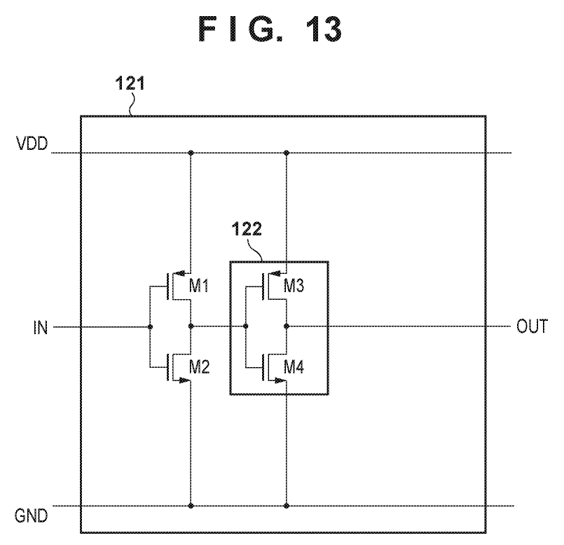

FIG. 13 shows an example in which none of the waveform controllers 123 to 125 are arranged. This is a so-called buffer configuration in which the transition times of rising and falling of the output signal OUT are decided by the element sizes of the transistors M3 and M4. The arrangements and configurations of the waveform controllers 123 to 125 can appropriately be set and can be designed in accordance with the application of a control signal, the layout area, power consumption, and the like.

The arrangement and configuration of the vertical scanning circuit 120 and the arrangement and configuration of the driver 121 described with reference to FIGS. 5 to 13 can also apply to the memory vertical scanning circuit 220 that forms a part of the signal generator shown in FIG. 1. In the explanation of this embodiment, the reference numerals of the driver 121 and the constituent elements of the driver 121 in the memory vertical scanning circuit 220 are the same as in the vertical scanning circuit 120. For example, the memory vertical scanning circuit 220 is configured to include a plurality of drivers 121 in accordance with a plurality of control signals for driving the transistors arranged in the pixel memories 40 or units of a single row to be driven or units of a plurality of rows to be driven. Also, in the configurations shown in FIGS. 5 to 13, the output signal OUT of the driver 121 continuously changes with respect to time, but the output signal may change from high to low or from low to high while holding a plurality of discrete levels for a predetermined time.

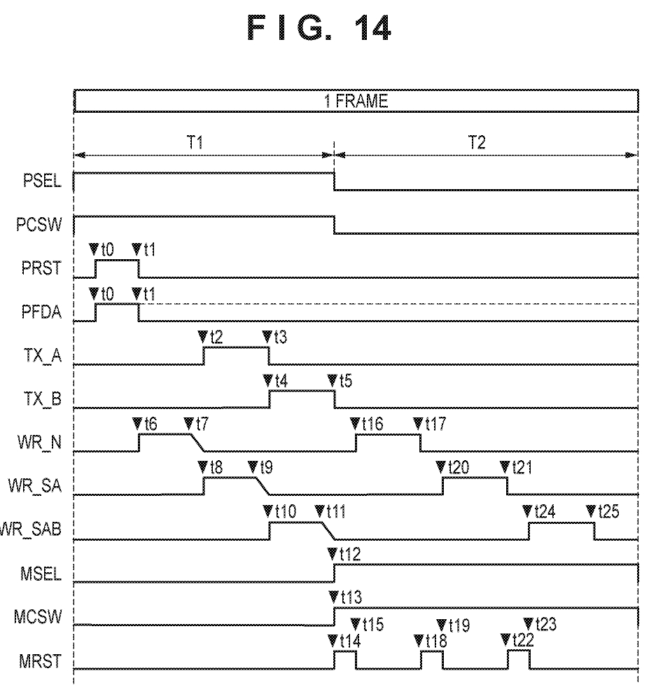

FIG. 14 is a view for explaining the operation timings of readout of signals in the pixel 30, the pixel memory 40, and the column signal processing circuit 50 shown in FIG. 3. A period T1 in which a charge signal generated by the PD 115 and the PD 116, which are photoelectric conversion elements, is held as a voltage signal in the signal holding memory mem and a period T2 in which the voltage signal held in the signal holding memory mem is A/D-converted by the column signal processing circuit 50 will be described with reference to FIG. 14. Each control signal is a signal output by the driver 121 as described above.

In FIG. 14, if the control signal supplied from the driver 121 is high, the transistor is turned on (conductive), and if the control signal is low, the transistor is turned off (nonconductive). The relationship between control signals and transistors operated by the control signals in FIG. 14 will be described while referring to FIG. 3. A charge signal generated by the PD 115 or the PD 116 that is a photoelectric conversion element and the voltage signal held by the signal holding memory mem will sometimes be referred to as a pixel signal together.

In the period T1, control signals PSEL and PCSW go high, and the pixel selection transistor 117 and the switch transistor 217 are turned on. A state in which signals can be supplied from the PDs 115 and 116 to the node CH via a source follower (SF) circuit formed by the pixel amplification transistor 111 and the current source transistor 216 is thus obtained. The SF circuit including the pixel amplification transistor 111 and the current source transistor 216 functions as an amplification circuit that outputs, to the node CH, a signal obtained by amplifying the signal level of a node N to which signals are supplied from the PDs 115 and 116 that are photoelectric conversion elements.

In a period from time t0 to t1, control signals PRST and PFDA go high, the pixel reset transistor 112 and the capacitor selection transistor 118 are turned on, and the FD capacitor 130 and the FDA capacitor 131 are reset to a potential level based on the reference power supply SVDD. This is a first reset period. When selecting the FDA capacitor 131, the control signal PFDA shown in FIG. 14 maintains the high state, as indicated by a dotted line. In the operation example shown in FIG. 14, the control signal PFDA goes low, and the FDA capacitor is not selected.

After completion of the first reset period, in a period from time t2 to t3, a control signal TX_A goes high, and the pixel transfer transistor 113 is turned on. Thus, a signal according to the signal level of the charge signal of the PD 115 is supplied to the node CH via the SF circuit formed by the pixel amplification transistor 111 and the current source transistor 216. This is a first transfer period. Similarly, in a period from time t4 to t5, a control signal TX_B goes high, and the pixel transfer transistor 114 is turned on. Thus, a signal according to the signal level of the charge signal of the PD 116 is supplied to the node CH via the SF circuit formed by the pixel amplification transistor 111 and the current source transistor 216. This is a second transfer period.

Control of the memory write transistors 213 to 215 and voltage signals held in the signal holding memories mem will be described next. After the end of the first reset period, in a period from time t6 to t7, a potential of noise level in the reset state of the FD capacitor (to be sometimes referred to as N level hereinafter) is supplied to the node CH via the SF circuit formed by the pixel amplification transistor 111 and the current source transistor 216. In this period, a control signal WR_N is set high at time t6 to turn on the memory write transistor 213, thereby sampling the N level in the signal holding memory Nmem, and the level is held at time t7. The period from time t8 to t9 is the first transfer period, and the potential (to be sometimes referred to as SA level hereinafter) in the FD capacitor 130 based on the signal level of the charge signal of the PD 115 is supplied to the node CH via the SF circuit formed by the pixel amplification transistor 111 and the current source transistor 216. In this period, a control signal WR_SA is set high at time t8 to turn on the memory write transistor 214, thereby sampling the SA level in the signal holding memory Smem-A, and the level is held at time t9. Similarly, the period from time t10 to t11 is the second transfer period, and the potential (to be sometimes referred to as SAB level hereinafter) in the FD capacitor 130 based on the signal level of the charge signal of the PD 116 is supplied to the node CH via the SF circuit formed by the pixel amplification transistor 111 and the current source transistor 216. In this period, a control signal WR_SAB is set high at time t10 to turn on the memory write transistor 215, thereby sampling the SAB level in the signal holding memory Smem-AB, and the level is held at time t11. By these operations, the N level, the SA level, and the SAB level are held as voltage signals in the signal holding memories Nmem, Smem-A, and Smem-AB, respectively. Here, the period to sample and hold the voltage signal in the signal holding memory mem is defined as a voltage holding operation period.

The series of operations from the first reset period to the voltage holding operation period is defined as a pixel signal voltage holding operation. When the pixel signal voltage holding operation is simultaneously performed in all pixels 30, a global electronic shutter operation can be implemented. The pixel signal voltage holding operation may be performed in all pixels 30 and pixel memories 40 among the plurality of pixels 30 and pixel memories 40, or the pixel signal voltage holding operation may be performed in some of these. For example, the pixel signal voltage holding operation may be performed sequentially in units of a plurality of pixel rows or in units of a plurality of pixel columns. Alternatively, the pixel signal voltage holding operation may be performed in each row.

After the pixel signal voltage holding operation, the voltage signal held in the signal holding memory mem is read out to the column signal processing circuit 50. In the period T2 shown in FIG. 14, the pixel selection transistor 117 is turned off. The pixel 30 and the pixel memory 40 are thus set in a nonconnection state. Also, when the switch transistor 217 is turned off, the current supplied by the current source transistor 216 is blocked, and the SF circuit formed by the pixel amplification transistor 111 and the current source transistor 216 is set in a nonoperation state. The node CH is thus set in a floating state. On the other hand, at time t12, a control signal MSEL goes high, and the memory selection transistor 218 is turned on, and at time t13 a control signal MCSW goes high, and the switch transistor 314 is turned on. The node CH is thus connected to the ADC 311, which is a processing circuit for performing A/D conversion of the signal of the column signal processing circuit 50, via the SF circuit formed by the memory amplification transistor 211 and the current source transistor 313. The SF circuit formed by the memory amplification transistor 211 and the current source transistor 313 functions as an amplification circuit that outputs a signal obtained by amplifying the signal level of the node CH. For example, the signal read out from the signal holding memory mem is amplified and supplied to the ADC 311. Here, time t12 and time t13 may be the same timing.

In a period from time t14 to t15, a control signal MRST goes high, the memory reset transistor 212 is turned on, and the node CH is reset to a potential level based on the reference power supply MVDD. This is a second reset period.

After the second reset period, in a period from time t16 to t17, the control signal WR_N is set high to turn on the memory write transistor 213, thereby outputting the voltage signal held in the signal holding memory Nmem to the node CH. The ADC 311 A/D-converts the voltage signal read out via the SF circuit formed by the memory amplification transistor 211 and the current source transistor 313 and held in the signal holding memory Nmem, that is, the voltage based on the N level. This is a first A/D conversion period. The potential of the node CH is decided in accordance with the ratio of the total capacitance value of the capacitance of the wiring pattern that forms the node CH, the diffusion capacitance of the memory write transistors 213 to 215, the gate capacitance of the memory amplification transistor 211, and the like to the capacitance value of the signal holding memory mem, and the potential difference of each node. For this reason, in the operation shown in FIG. 14, the second reset period is provided to reset the node CH to a predetermined potential before the voltage held in each signal holding memory mem is read out.

After the second reset period performed from time t18 to t19, in a period from time t20 to t21, the control signal WR_SA is set high to turn on the memory write transistor 214. The voltage signal held in the signal holding memory Smem-A is thus output to the node CH. The ADC 311 A/D-converts the voltage signal read out via the SF circuit formed by the memory amplification transistor 211 and the current source transistor 313 and held in the signal holding memory Smem-A, that is, the voltage based on the SA level. This is a second A/D conversion period.

After the second reset period performed from time t22 to t23, in a period from time t24 to t25, the control signal WR_SAB is set high to turn on the memory write transistor 215. The voltage signal held in the signal holding memory Smem-AB is thus output to the node CH. The ADC 311 A/D-converts the voltage signal read out via the SF circuit formed by the memory amplification transistor 211 and the current source transistor 313 and held in the signal holding memory Smem-AB, that is, the voltage based on the SAB level. This is a third A/D conversion period.

After the third A/D conversion period, the period T2 ends, and the memory selection transistor 218 and the switch transistor 314 are turned off. The pixel memory 40 and the column signal processing circuit 50 are thus set in a nonconnection state. Also, when the switch transistor 314 is turned off, the current supplied by the current source transistor 313 is blocked, and the SF circuit formed by the memory amplification transistor 211 and the current source transistor 313 is set in a nonoperation state.

In the operation shown in FIG. 14, the reset operation of the PDs 115 and PD 116 which are photoelectric conversion elements is not clearly provided but, for example, times after the first transfer period and the second transfer period may be accumulation start times. Also, in the period T2 or at a timing (not shown) other than the periods T1 and T2, the pixel transfer transistor 113, the pixel transfer transistor 114, the pixel reset transistor 112, and the capacitor selection transistor 118 are turned on. The PD 115 and the PD 116 may be thus reset to a potential based on the reference power supply SVDD. Although not shown in FIG. 3, a PD reset transistor may be provided between the PDs 115 and 116 and the reference power supply SVDD to perform the reset operation.

For example, the vertical scanning circuit 120 and the memory vertical scanning circuit 220 can control, in the plurality of pixels 30, the pixels 30 arranged in one row via a common control signal line, and can control, via a common control signal line, the memory write transistors 213 to 215 configured to holdsignals in the signal holding memories mem corresponding to the photoelectric conversion elements (PDs 115 and 116) arranged in the pixels 30 arranged in one row. Also, for example, the vertical scanning circuit 120 and the memory vertical scanning circuit 220 may control, in the plurality of pixels 30, the pixels 30 arranged in two or more rows via a common control signal line, and may control, via a common control signal line, the memory write transistors 213 to 215 configured to holdsignals in the signal holding memories mem corresponding to the photoelectric conversion elements (PDs 115 and 116) arranged in the pixels 30 arranged in two or more rows. The vertical scanning circuit 120, the memory vertical scanning circuit 220, and the column control circuit 320, which form the signal generator, simultaneously drive and control the plurality of pixels 30, simultaneously drive and control the memory write transistors 213 to 215 corresponding to the photoelectric conversion elements arranged in the plurality of pixels, and simultaneously drive and control a plurality of processing circuits (column signal processing circuits 50) corresponding to the photoelectric conversion elements arranged in the plurality of pixels 30. Thus, the global electronic shutter operation is implemented in the photoelectric conversion apparatus 10.

In FIG. 14, as for times t7, t9, and t11 at which the voltage signals are held in the signal holding memories mem during the period T1, the waveform controller 124 of the driver 121 is controlled, thereby controlling the transition time of falling. Hence, the transition time is longer than the falling transition times of other control signals or the rising transition time of the control signal. That the transition time is long means that the time necessary for switching between high and low of the control signal is intentionally made longer than, for example, a delay time generated in the parasitic capacitance of the wiring pattern. This can also be expressed as delaying the rising and falling transition times of the control signal. Controlling and delaying the rising and falling transition times of the control signal can also be expressed as making the control signal dull. In the example shown in FIG. 14, at times t7, t9, and t11, the transition time between two voltages, in which the control signals WR_N, WR_SA, and WR_SAB for controlling the memory write transistors 213 to 215 arranged between the node CH and the signal holding memories mem transition from high to low (if the control signals need not be discriminated, these will sometimes be referred to as control signals WR hereinafter) is longer than the transition time in which the control signals PSEL and PCSW for selecting the SF circuit formed by the pixel amplification transistor 111 and the current source transistor 216 and functioning as an amplification circuit transition between low and high.

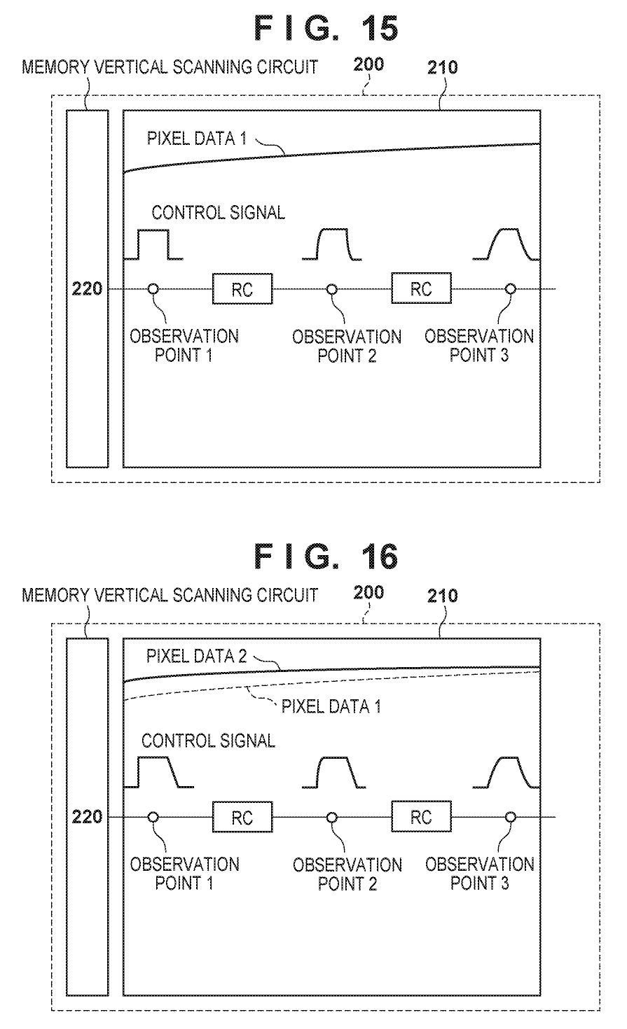

An example of the relationship between the transition time of falling of the control signal WR and obtained pixel data will be described here with reference to FIGS. 15 and 16. In FIGS. 15 and 16, the substrate 200, the memory region 210, and the memory vertical scanning circuit 220 shown in FIG. 1 are extracted, and for the control signal WR output from the memory vertical scanning circuit 220, waveforms at arbitrary observation points 1 to 3 in the row direction are shown. In addition, FIGS. 15 and 16 show the distribution of pixel data of an arbitrary row. Also, the parasitic resistance and the parasitic capacitance of the control signal line to which the control signal WR is supplied and the gate parasitic loads of the transistors forming the pixel memory 40 are indicated by a parasitic load RC together. As shown in FIG. 15, the waveform of the control signal WR changes at observation points 1 to 3 because of the influence of the parasitic load RC. In FIG. 15, as compared to the transition times of rising and falling of the control signal WR at observation point 1, the transition times of rising and falling of the control signal WR are long due to the influence of the parasitic load RC at observation points 2 and 3 where the control signal line from the driver 121 is long.

The voltage signals held in the signal holding memories mem are sometimes affected by switching noise when the memory write transistors 213 to 215 are turned off. For example, when the transistor changes from the ON state to the OFF state, a phenomenon called channel charge injection may occur in which a charge held in the channel of the transistor flows out to the source and drain of the transistor. This is held as an offset voltage in the signal holding memory mem and is an error component for pixel data. If the memory write transistors 213 to 215 are n-type transistors, the voltage is generally held as a negative offset voltage. In another example, the change of the control signal WR for controlling the memory write transistors 213 to 215 may change the voltage signal held in the signal holding memory mem via an overlap capacitance formed between the gate and the drain of each of the memory write transistors 213 to 215 or between the gate and the source. The influence of the switching noise may change depending on the transition time of falling of the control signal WR.

FIG. 15 shows an example in which the pixel region 110 is uniformly in a dark state. In this case, the pixels 30 have the same output characteristic, and pixel data ideally has an even output characteristic, in other words, a flat output. The influence of switching noise changes depending on the difference of the control signal WR at observation points 1 to 3, particularly, the difference of the falling transition time and, for example, a gradient of the output may occur in the row direction, like pixel data 1 shown in FIG. 15. The gradient of the output in the row direction is one of image quality performances called shading, and the image quality performance degrades as the gradient becomes large.

FIG. 16 shows an example in which, for example, the driver 121 has the configuration shown in FIG. 10, and the waveform controller 124 is controlled, thereby making the transition time of falling of the control signal WR long. When the falling transition time of the control signal WR at observation point 1 is made longer as compared to the case shown in FIG. 15, the transition time of falling of the control signal WR at observation point 3 is close to the transition time at observation point 1. It is therefore possible to make the characteristic close to the characteristic of the switching noise between observation point 1 and observation point 3, and the gradient of the output in the row direction can be reduced, like pixel data 2. This reduces shading, that is, degradation of image quality performance can be suppressed.

As for the influence of the switching noise derived from the transition time of falling of the control signal WR, another example will be described next with reference to FIGS. 17 to 19. FIG. 17 is a view for explaining the distribution of pixel data corresponding to the pixel region 110 in a case where a part of the pixel region 110 is irradiated with light. In FIG. 17, some of the pixels 30 arranged near observation point 2 at vertical position 2, that is, only a region near the center of the pixel region 110 is irradiated with light, and observation points 1 to 3 at vertical positions 1 and 3 and observation points 1 and 3 at vertical position 2 are in the dark state. If there is no shading in the row direction, an output according to the input light is obtained at observation point 2 at vertical position 2, and a predetermined output in the dark state is obtained at observation points 1 and 3. On the other hand, at vertical positions 1 and 3, observation points 1 to 3 are uniformly in the dark state, and a predetermined output in the dark state is obtained, as shown in FIG. 17.

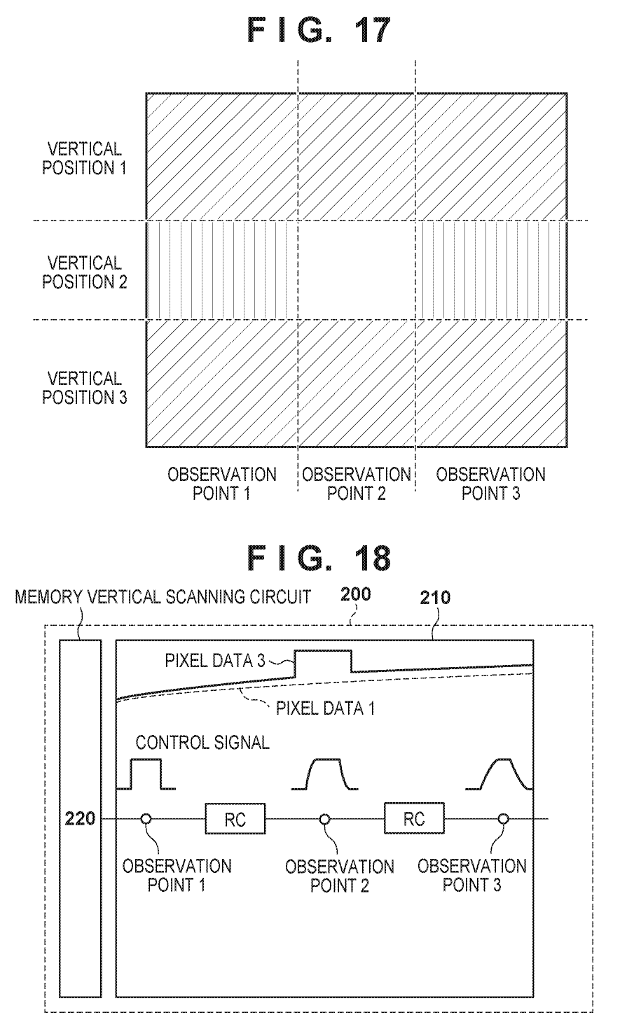

In FIG. 18, like FIGS. 15 and 16, the substrate 200, the memory region 210, and the memory vertical scanning circuit 220 shown in FIG. 1 are extracted, and for the control signal WR output from the memory vertical scanning circuit 220, waveforms at arbitrary observation points 1 to 3 in the row direction are shown. In addition, FIG. 18 shows the distribution of pixel data of an arbitrary row. In FIG. 17, the influence of shading in the row direction is assumed to be absent. In FIG. 18, reflecting the influence of shading in the row direction, the same distribution of pixel data in the horizontal direction as in FIG. 15 is obtained for positions 1 and 3, and this is indicated as pixel data 1. At vertical position 2, light is input at observation point, and observation points 1 and 3 are in the dark state. Hence, the distribution of pixel data in the row direction is indicated by pixel data 3. In FIG. 18, a control signal corresponding to vertical position 2 in FIG. 17 is shown.

As described with reference to FIG. 14, for example, the voltage signal is held in the signal holding memory Smem-A at the timing at which the memory write transistor 214 is turned off. Here, the timing at which the memory write transistor 214 is turned off is the timing at which the voltage level of the control signal WR_SA transitions from high to low and the potential difference between the gate and the source of the memory write transistor 214 is not more than the threshold of the memory write transistor 214. If the pixel 30 at observation point 2 at vertical position 2 is irradiated with light, the voltage signal held in the corresponding signal holding memory Smem-A has a low signal level as compared to a case where there is no light irradiation. In this case, when the voltage level of the control signal WR_SA of the memory write transistor 214 transitions from high to low, the potential difference between the gate and the source of the memory write transistor 214 becomes not more than the threshold of the transistor at a low voltage as compared to a case where there is no light input. That is, the timing at which the memory write transistor 214 is turned off is delayed at observation point 2 at vertical position 2 as compared to vertical positions 1 and 3 in the dark state or observation points 1 and 3 at vertical position 2. As described above, the waveform of the control signal WR changes depending on the parasitic load of the wiring pattern or the gate loads of transistors forming the pixel memory 40. The overlap capacitance that is one of the gate loads of the transistor changes between the ON state and the OFF state of the transistor. In general, the overlap capacitance is smaller in the OFF state of the transistor than in the ON state.

In the case shown in FIGS. 17 and 18, if it is assumed that there is no shading in the row direction, concerning the row corresponding to vertical position 2, at the timing at which the memory write transistors 214 at observation points 1 and 3 are turned off, the memory write transistor 214 at observation point 2 is not turned off. On the other hand, at the timing at which the memory write transistors 214 are turned off at observation points 1 and 3 at vertical positions 1 and 3, the memory write transistor 214 at observation point 2 is also turned off. For this reason, at the timing at which the memory write transistor 214 is turned off, the gate load associated with the memory write transistors 214 at vertical position 2, that is, the parasitic load is larger as compared to vertical positions 1 and 3. That is, at the timing at which the memory write transistor 214 is turned off, since the waveform of the control signal WR changes between vertical positions 1 and 3 and vertical position 2 due to the difference of the parasitic load on the control signal line, the influence of switching noise may be different. Hence, the pixel data at observation points 1 and 3 at vertical position 2 shown in FIG. 18 is the pixel data when the pixel 30 is in the dark state, but the pixel data in the dark state at observation points 1 and 3 changes between a case where the whole region is in the dark state, as shown in FIG. 15, and a case where light is input to observation point 2, as shown in FIG. 18. Thus, a difference like that between pixel data 1 and pixel data 3 shown in FIG. 18 may be generated. Referring to FIG. 17, this is the difference between the pixel data at observation points 1 and 3 in the dark state at vertical position 2 where light is input and the pixel data at observation points 1 and 3 at vertical positions 1 and 3 where light is not input. This means that even in the same dark state, a step difference may occur in the pixel data at the boundary between vertical positions 1 and 3 and vertical position 2, and the image quality performance may degrade.

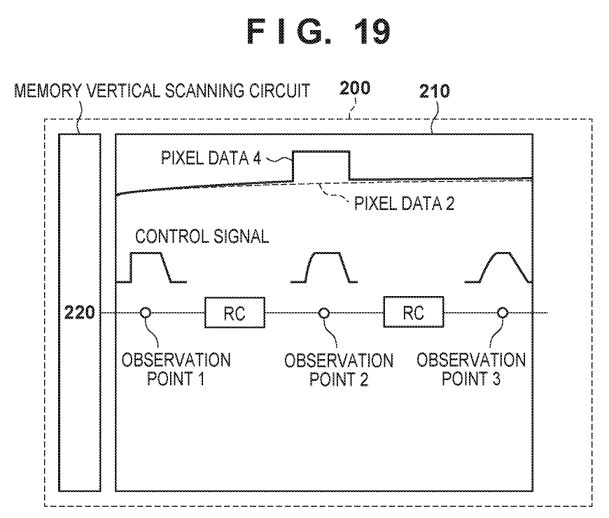

In FIG. 19, the transition time of falling of the control signal WR is controlled as in the case shown in FIG. 16. In the rows corresponding to vertical positions 1 and 3 in FIG. 17, the distribution of pixel data in the row direction is the same as that of pixel data 2, like FIG. 16. On the other hand, at vertical position 2, if the transition time of falling of the control signal WR to be controlled by the driver 121 is sufficiently long with respect to the change of the control signal WR with respect to the change of the gate load of the transistor caused by irradiation of light, the change of the control signal WR depending on the irradiation of light can be reduced. For this reason, as shown in FIG. 17, even if there is a difference between the dark state and the light irradiation state depending on the vertical position, the difference of the influence of switching noise between the vertical positions can be reduced, and the distribution of pixel data at vertical position 2 is indicated by pixel data 4. That is, the difference between the pixel data in the dark state in the row irradiated with light and the pixel data in the dark state in the row that is not irradiated with light decreases, and degradation of the image quality performance can be suppressed.

Here, the relationship between the change of the waveform caused by the parasitic load RC and the transition times of rising and falling of the waveform by the waveform controller of the driver 121 will be described. More specifically, the change of the waveform caused by the parasitic load RC corresponds to the time of charging/discharging the parasitic load RC by the driver 121. As described with reference to FIGS. 14 to 19, the influence of switching noise changes depending on the difference of the transition times of rising and falling of the control signal WR, resulting in degradation of the image quality performance. If the transition times of rising and falling of the waveform controlled by the waveform controller of the driver 121 are sufficiently long with respect to the transition times of rising and falling of the control signal WR by the parasitic load RC, the difference of the influence of switching noise can be reduced, and degradation of the image quality performance can be suppressed. That the transition time is sufficiently long means that the influence of the transition time change by the parasitic load RC is sufficiently small. More specifically, for example, assume that the transition time derived from the parasitic load RC at observation point 1 in FIG. 15 is 1 [μsec], and the transition time derived from the parasitic load RC at observation point 3 is 10 [μsec]. In this case, the difference in the transition time is 10 times. For example, if the transition time controlled using the waveform controller of the driver 121 is 100 [μsec], it can be considered that the transition time at observation point 1 is 101 [μsec] and the transition time at observation point 3 is 110 [μsec]. In this case, the difference in the transition time can be decreased to 1.1 times, and the degradation of the image quality performance caused by the difference of the influence of switching noise can be suppressed to 1/10 as compared to a case where the transition time is not controlled. For example, the driver 121 may generate the control signal WR such that the difference between the transition time of falling of the control signal WR in the memory write transistor corresponding to the photoelectric conversion element of the pixel 30 arranged at observation point 1 and the transition time of falling of the control signal WR in the memory write transistor corresponding to the photoelectric conversion element of the pixel 30 arranged at observation point 3 is 10% or less. As described above, the length of the control signal line from the driver 121 to the memory write transistor corresponding to the photoelectric conversion element of the pixel 30 at observation point 1 and the length of the control signal line from the driver 121 to the memory write transistor corresponding to the photoelectric conversion element of the pixel 30 at observation point 3 are different. For example, on the common control signal line to which memory write transistors corresponding to the photoelectric conversion elements of the pixels 30 at observation points 1, 2, and 3 are connected, the memory write transistor at observation point 1 may be a transistor whose length from the driver 121 on the control signal line is shortest. In addition, the memory write transistor at observation point 3 may be a transistor whose length from the driver 121 on the control signal line is longest. That is, the driver 121 may generate the control signal WR such that the difference from the transition times of falling of the control signal WR in all memory write transistors connected to the same control signal line is 10% or less.

In addition, depending on the configuration of the waveform controller, the control amount of the transition time and the degree of suppression of degradation of the image quality performance may change. This is because, for example, the waveform of the control signal at observation points 1 and 3 is different between a case where the transition time is controlled by the charging/discharging operation of the parasitic load RC by a current source using the driver 121 shown in FIGS. 10 or 11 and a case where the transition time is controlled by control based on current suppression using the variable resistive element RES shown in FIG. 12. Considering these, when the transition time by control using the waveform controller of the driver 121 is set to about 5 times to 10 times the transition time derived from the parasitic load RC, degradation of the image quality performance caused by the difference of the influence of switching noise can mostly be suppressed. The control amount of the transition time can also be set in accordance with the required specifications of image quality performance. Also, if a gain is applied by the column signal processing circuit 50 or another signal processing, the influence of switching noise held in the signal holding memory mem may be enhanced. In this case, it is possible to increase the control amount of the transition time and thus reduce the difference of the influence of switching noise. Note that in this embodiment, the transition time is the transition time between high level and low level of the control signal. More specifically, as for the level difference between high and low, for example, low may be defined as 10 [%], and high may be defined as 90 [%]. Also, the transition time may be defined based on the levels to sufficiently turn on/off each transistor.

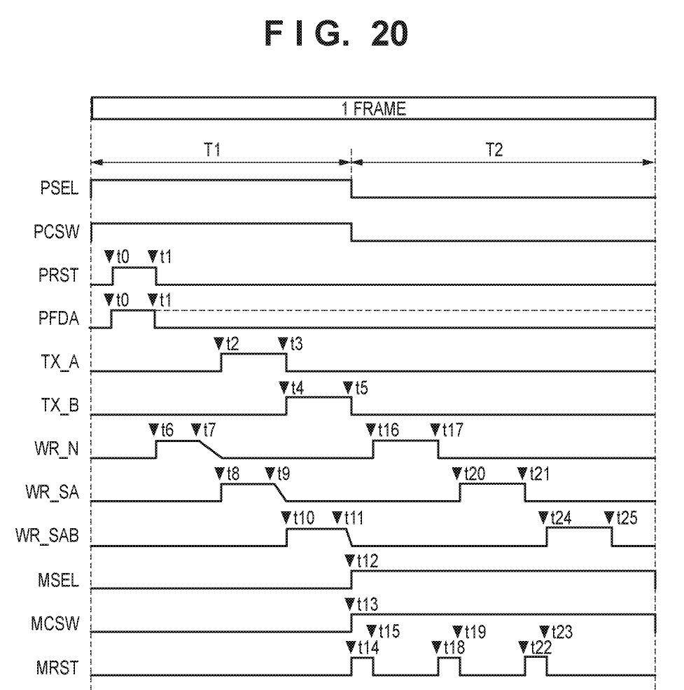

FIG. 20 is a view for explaining an operation timing different from the operation timing described with reference to FIG. 14. For example, the photoelectric conversion apparatus 10 may be configured to be operable by switching between a driving mode to perform the operation shown in FIG. 14 and a driving mode to perform the operations shown in FIGS. 20 to 23 to be described below. Also, for example, the photoelectric conversion apparatus 10 may have a driving mode not to control the transition time.

In the operation shown in FIG. 20, concerning the control signals WR_N, WR_SA, and WR_SAB in the period T1, the transition times of falling are different from those in FIG. 14. More specifically, the driver 121 operates such that the transition time of falling of the control signal WR when a signal of N level according to the noise level of the node N is held in the signal holding memory Nmem that is a holding capacitor and the transition time of falling of the control signals WR_SA and WR_SAB when signals of SA level and SAB level according to the signal level supplied from the PDs 115 and 116 are held in the signal holding memories Smem-A and Smem-AB are different. Furthermore, the driver 121 operates such that the transition time of falling of the control signal WR_SA when a signal of SA level according to the signal level supplied from the PD 115 is held in the signal holding memory Smem-A and the transition time of falling of the control signal WR_SAB when a signal of SAB level according to the signal level supplied from the PDs 115 and 116 is held in the signal holding memory Smem-AB are different. At this time, the driver 121 makes the transition time of falling of the control signals WR_SA and WR_SAB shorter than that of the control signal WR_N. In addition, the driver 121 makes the transition time of falling of the control signal WR_SAB shorter than that of the control signal WR_SA.

If light of a predetermined amount enters the pixel region 110, the magnitude relationship between the voltage signals held in the signal holding memories mem is represented by signal holding memory Nmem > signal holding memory Smem-A > signal holding memory Smem-AB. That is, as described with reference to FIGS. 17 to 19, the time until the OFF state is different between the memory write transistors 213 to 215 depending on the difference of the signal level held in the signal holding memory mem. In this embodiment, the relationship between the times until the OFF state is represented by memory write transistor 213 < memory write transistor 214 < memory write transistor 215. For example, the driver 121 for generating the control signal WR operates such that the longer the time until the OFF state is, the longer the transition time of falling of the control signal WR is. That is, when the memory write transistors 213 to 215 are controlled as shown in FIG. 20, the difference of the transition time of falling of the control signal WR decreases in the voltage holding operation of each signal holding memory mem. This can decrease the difference of the influence of switching noise associated with the OFF operation of the memory write transistors 213 to 215. If the pixel has the PDAF function, like the pixel 30 according to this embodiment, a phase difference is calculated by the operation of the voltage signals held in the signal holding memory Smem-A and the signal holding memory Smem-AB. As shown in FIG. 20, when the difference of the influence of switching noise associated with the OFF operation is reduced between the signal holding memories mem, the offset difference of the held voltage signals can be reduced, and the detection accuracy of the phase difference can be improved.

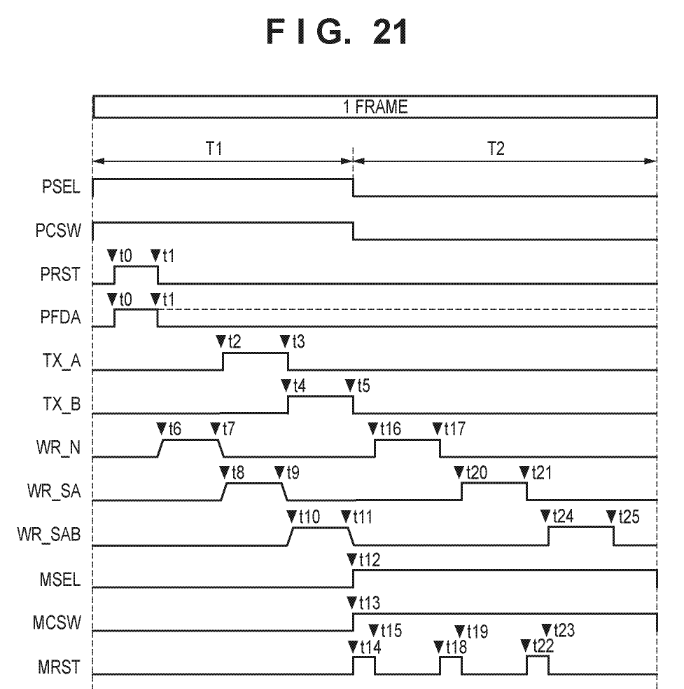

FIG. 21 is a view for explaining an operation timing different from the operation timing described with reference to FIG. 14. In the operation shown in FIG. 21, concerning the control signals WR_N, WR_SA, and WR_SAB in the period T1, not only the transition time of falling but also the transition time of rising is controlled, as compared to FIG. 14.

For example, when performing the global electronic shutter operation, all pixels 30 and pixel memories 40 can be controlled. In the global electronic shutter operation, concerning the pixel memories 40 according to the number of pixels 30, the memory write transistors 213 to 215 in the period T1 are simultaneously turned on/off. In this case, in the control signal lines of the control signals WR_N, WR_SA, and WR_SAB for controlling the memory write transistors 213 to 215 of the pixel memories 40, a level change between high and low occurs simultaneously in rows according to the number of pixels 30. For example, a parasitic capacitance between wirings may exist between each control signal line and the reference power supplies MVDD and MGND. If the level of the control signal line changes between high and low, the potentials of the reference power supplies MVDD and MGND may transiently vary via the parasitic capacitance. If the global electronic shutter operation is performed, the transient potential variations of the reference power supplies MVDD and MGND occur in the entire memory region 210, and the potential variation amount can be large as compared to a case where driving is performed in units of a row like a rolling shutter operation. Also, when the plurality of drivers 121 in the memory vertical scanning circuit 220 simultaneously operate, for example, the reference power supplies VDD and GND of the drivers 121 shown in FIG. 5 transiently vary, and the variation amount is large as compared to a case where driving is performed in units of one or more rows.

Before the variations of the reference power supplies MVDD and MGND associated with the global electronic shutter operation settle, for example, if the holding operation of the signal holding memory mem is performed in the period T1, this may cause an error in the held voltage signal or noise and degrade the image quality performance. Similarly, before the variations of the reference power supplies MVDD and MGND associated with the global electronic shutter operation settle, if the voltage signal held in the signal holding memory mem is A/D converted by the ADC 311 in the period T2, this may cause an error of the A/D conversion value and degrade the image quality performance. Also, in a case where the reference power supplies VDD and GND are varying, if one of the control signals WR is controlled before these settle, levels corresponding to high and low vary and, therefore, the ON/OFF timing of each transistor may vary, or an operation error may occur. For example, the charge accumulation or charge transfer operation of the pixel 30 may vary, or the voltage signal held in the signal holding memory mem may vary, resulting in degradation of the image quality performance. If the transition times of rising and falling of the control signals WR_N, WR_SA, and WR_SAB are controlled, as shown in FIG. 21, these transient potential variation amounts can be reduced, and degradation of image quality can be suppressed. The transition time of rising and the transition time of falling may be equal or different. Also, like the operation shown in FIG. 20, the transition time of rising or the transition time of falling may be different in each of the control signals WR_N, WR_SA, and WR_SAB.

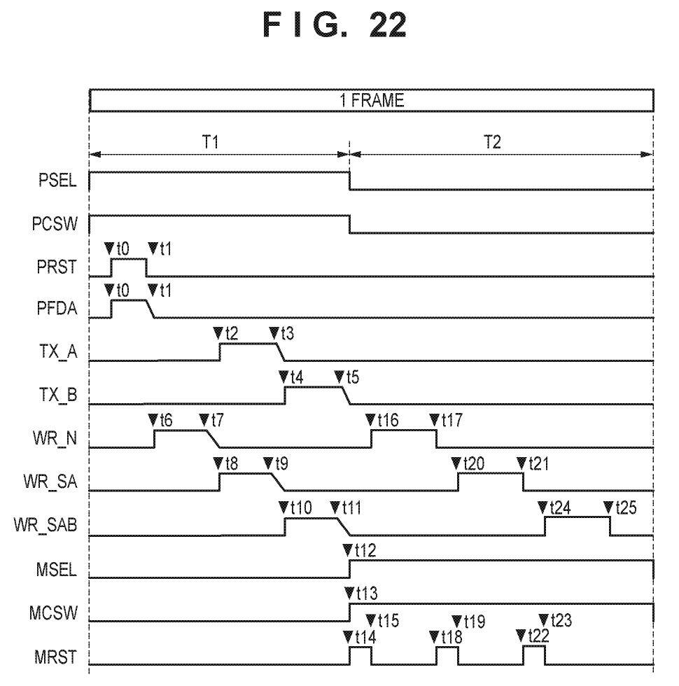

In the operation shown in FIG. 22, the transition time of falling is controlled not only for the control signals WR_N, WR_SA, and WR_SAB but also for the control signals TX_A and TX_B for controlling the ON state and the OFF state of the pixel transfer transistors 113 and 114. Also, in the operation shown in FIG. 22, the transition time of falling is controlled for the control signal PFDA for controlling the ON state and the OFF state of the capacitor selection transistor 118. For example, the transition times of falling of the control signals TX_A and TX_B affect the charge transfer characteristic from the PDs 115 and 116 to the FD capacitor 130. Similarly, the transition time of falling of the control signal PFDA affects switching noise when the capacitor selection transistor 118 is turned off, and an offset voltage may be held in the FD capacitor 130. That is, even in controlling the control signals TX_A and TX_B or the control signal PFDA, the same influence as the influence of switching noise of the memory write transistors 213 to 215 on the image quality performance described with reference to FIGS. 15 to 19 may occur. In the operation shown in FIG. 22, the transition time of falling is controlled for the control signals TX_A and TX_B of the pixel transfer transistors 113 and 114 and the control signal PFDA of the capacitor selection transistor 118, thereby suppressing degradation of the image quality performance.

In the global electronic shutter operation, the control signals TX_A and TX_B for controlling all pixels 30 simultaneously change between high and low. In addition, if the capacitor selection transistors 118 are simultaneously switched and used in all pixels 30, the control signal PFDA corresponding to all pixels 30 changes between high and low. This may cause transient potential variations in the reference power supplies SVDD and SGND, like the variations of the reference power supplies associated with the global electronic shutter operation described with reference to FIG. 21. If the voltage signal holding operation of the signal holding memory mem or the charge transfer operation from the PDs 115 and 116 to the FD capacitor 130 is performed before the transient potential variations of the reference power supplies SVDD and SGND settle, an error or variations of pixel signals may occur, resulting in degradation of the image quality performance. Also, for the vertical scanning circuit 120, the reference power supplies VDD and GND may transiently vary, like the memory vertical scanning circuit 220. If the voltage signal holding operation of the signal holding memory mem or the charge transfer operation from the PDs 115 and 116 to the FD capacitor 130 is performed in a state in which the transient potential variations of the reference power supplies VDD and GND do not settle, an error or variations of pixel signals may occur, resulting in degradation of the image quality performance. Hence, in the operation shown in FIG. 22, the control signals TX_A and TX_B and the control signal PFDA are delayed by controlling the transition time of falling. However, like the operation shown in FIG. 21, the transition times of rising of the control signals may be controlled.

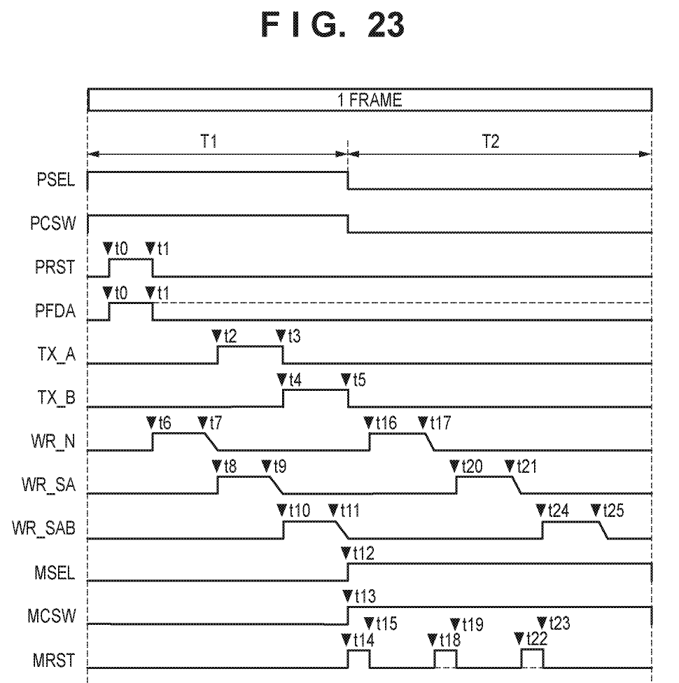

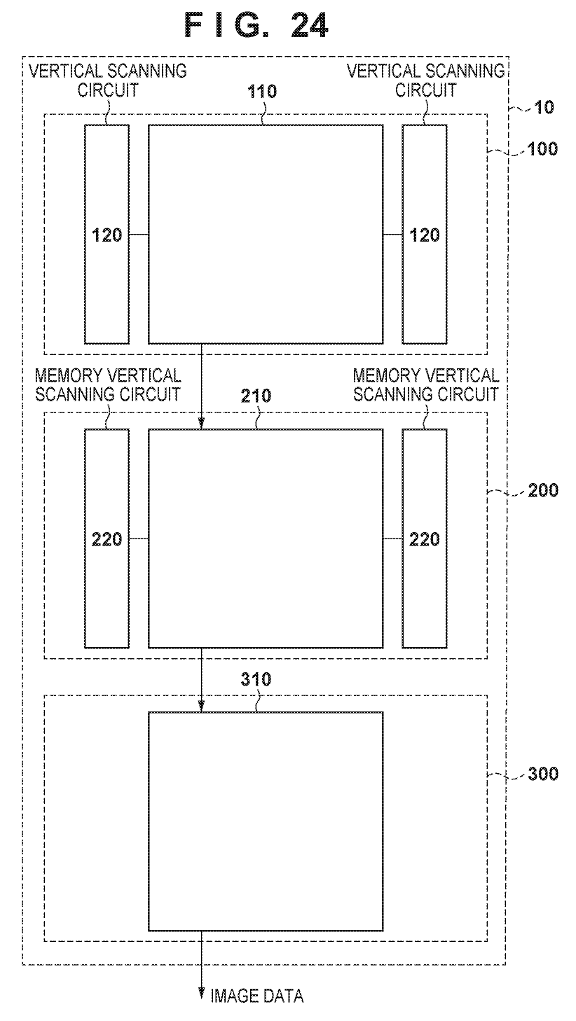

In the operation shown in FIG. 23, the transition times of falling of the control signals WR_N, WR_SA, and WR_SAB are controlled not only in the period T1 but also in the period T2. In the above-described operation examples, the transition times are controlled in the operation when holding the signal of the node CH in the signal holding memory mem. Hence, in the operation when holding the signal of the node CH in the signal holding memory mem, the transition time of at least one of falling and rising is longer than the transition times of rising and falling even when supplying the signal level of the signal holding memory mem to the node CH. In the operation example shown in FIG. 23, furthermore, the transition time is controlled even when supplying the signal level of the signal holding memory mem to the node CH.

For example, there may be a case where at time t18 to t19 and time t22 to t23, the control signal MRST is set low not to perform reset of the node CH by the memory reset transistor 212, as indicated by the dotted line of the control signal MRST. This can reduce the influence of switching noise when turning off the memory reset transistor 212 and making the period T2 short by omitting time t18 to t19 and time t22 to t23. In addition, power associated with the reset of the node CH by the memory reset transistor 212 can be reduced. If the reset operation of the node CH by the memory reset transistor 212 is absent, there is the influence of switching noise on the node CH in association with the OFF operation of the control signals WR_N, WR_SA, and WR_SAB. Depending on the arrangement position of the pixel memory 40 or the level of the voltage signal held in each signal holding memory mem, a difference may be generated in the influence of switching noise on the node CH in association with the OFF operation of the control signals WR_N, WR_SA, and WR_SAB. This may degrade the image quality performance, like the influence of switching noise on the image quality performance described with reference to FIGS. 15 to 19. Hence, as shown in FIG. 23, the transition times of falling of the control signals WR_N, WR_SA, and WR_SAB are delayed in the period T2, thereby reducing the difference of the influence of switching noise by an observation point or light input and suppressing degradation of the image quality performance.

FIG. 24 is a view focusing on the arrangement of the vertical scanning circuit 120 and the memory vertical scanning circuit 220 according to this embodiment in which some of the constituent elements described with reference to FIG. 1 are omitted. In the configuration shown in FIG. 24, the vertical scanning circuits 120 are arranged to sandwich the pixel region 110 on the substrate 100, as compared to the configuration shown in FIG. 1. In addition, on the substrate 200, the memory vertical scanning circuits 220 are arranged to sandwich the memory region 210 in which the pixel memories 40 each including the signal holding memories mem are arranged. Thus, the vertical scanning circuits 120 and the memory vertical scanning circuits 220 supply control signals from the left and right sides.

In the operation examples shown in FIGS. 14 and 20 to 23, the transition times of rising and falling are controlled for each control signal. However, the present disclosure is not limited to these examples. The presence/absence of control of one of the transition times of rising and falling of a control signal or both transition times may be set for each control signal, or the control amount of each transition time may be changed. Also, like the periods T1 and T2, the presence/absence of control of one of the transition times of rising and falling or the control amount may be changed depending on the timing of driving. For example, in the operation shown in FIG. 23, the transition time of falling in the operation when holding the signal of the node CH in the signal holding memory mem is longer than the transition times of falling when supplying the signal level of the signal holding memory mem to the node CH. However, the present disclosure is not limited to this, and the transition times may be equal, or the transition time of falling when supplying the signal level of the signal holding memory mem to the node CH may be longer. In addition, the operations shown in FIGS. 14 and 20 to 23 may appropriately be combined.

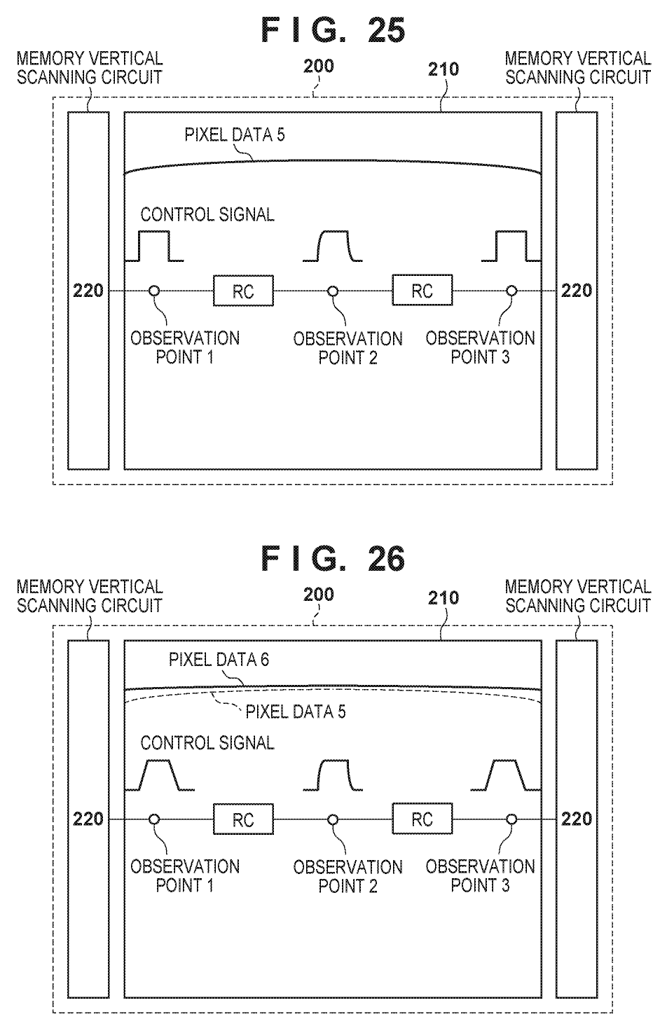

In FIG. 25, concerning the configuration shown in FIG. 24, the substrate 200, the memory region 210, and the memory vertical scanning circuit 220 shown in FIG. 1 are extracted. Also, in FIG. 25, for the control signal (for example, the control signal WR) output from the memory vertical scanning circuit 220, waveforms at arbitrary observation points 1 to 3 in the row direction are shown, like FIGS. 15 and 16. In addition, FIG. 25 shows the distribution of pixel data of an arbitrary row. Like the configuration shown in FIG. 24, the control signals are supplied from the left and right sides of the memory region 210, similar waveforms are obtained at observation point 1 and observation point 3. On the other hand, because of the difference to the waveform between observation points 1 and 3 and observation point 2, for example, pixel data 5 may have such a distribution in the row direction that the output difference is generated between the center and the left and right sides. FIG. 26 shows an example in which, as described above, the transition times of rising and falling of the control signal are controlled, thereby reducing the difference of the transition times of falling and rising of the waveforms at observation points 1 to 3 and reducing the influence of the difference of the characteristic of switching noise between the observation points. As indicated by pixel data 6 shown in FIG. 26, a distribution in the row direction in which the difference between the center and the left and right sides is reduced is implemented, and degradation of the image quality performance is suppressed, as compared to pixel data 5.

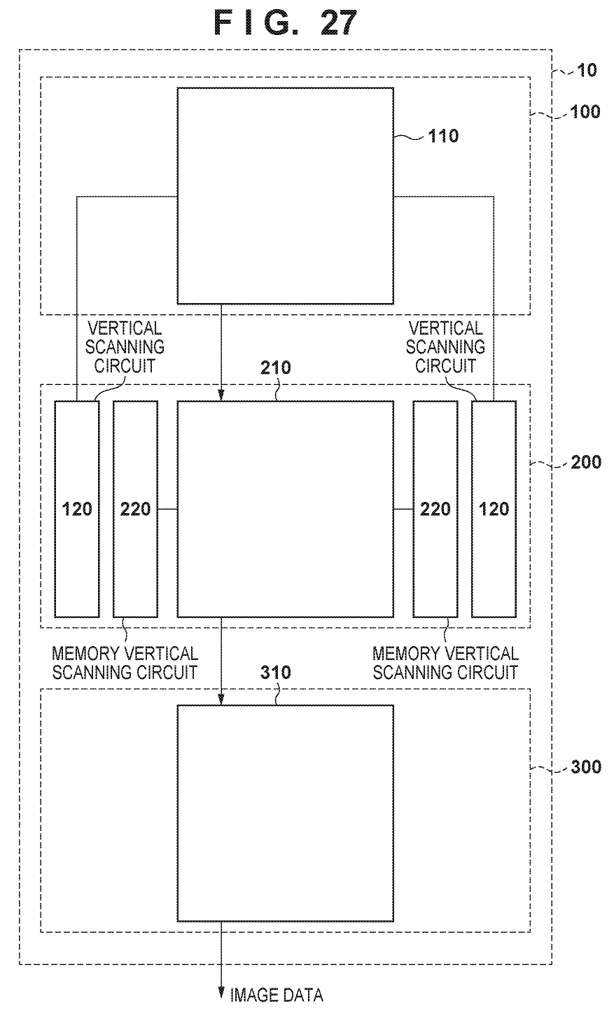

FIG. 27 is a view showing a modification of FIG. 24, focusing on the arrangement of the vertical scanning circuit 120 and the memory vertical scanning circuit 220. As compared to FIG. 24, the vertical scanning circuits 120 and the memory vertical scanning circuits 220 are arranged on the substrate 200. The configuration shown in FIG. 27 also shows an example in which the control signals are supplied from the left and right sides of the pixel region 110 and the memory region 210. For example, on the substrate 100, tuning of the manufacturing process of the PDs 115 and 116 and the pixel transfer transistors 113 and 114 is sometimes needed to improve the performance of the pixels 30. In this case, it may be impossible to arrange the constituent elements of the vertical scanning circuit 120, or even if they are arranged, a desired characteristic may not be obtained. In this case, like the example shown in FIG. 27, the vertical scanning circuit 120 may be arranged on the substrate 200 that is another chip to control the pixels 30. The vertical scanning circuits 120 and the memory vertical scanning circuits 220, which form the signal generator and are arranged on the substrate 200, generate the control signals for controlling the components arranged on the substrate 100 and the substrate 200 in the photoelectric conversion apparatus 10.

In the configuration shown in FIG. 27, the control signals are supplied from the vertical scanning circuits 120 arranged on the substrate 200 to the pixel region 110 on the substrate 100 via one wiring pattern. However, in the actual configuration, the substrate 100 and the substrate 200 can be connected by the same configuration as the joint portion 400 shown in FIG. 3. Also, the control signals may be supplied to the pixel region 110 in which the pixels 30 are arranged in an array via a plurality of joint portions 400 arranged in an array. Alternatively, for example, a plurality of joint portions 400 corresponding to the number of rows of pixels 30 arranged in the column direction may be arranged on the left and right sides of the pixel region 110 and connected to the vertical scanning circuits 120 arranged on the substrate 200 to control the plurality of pixels 30.

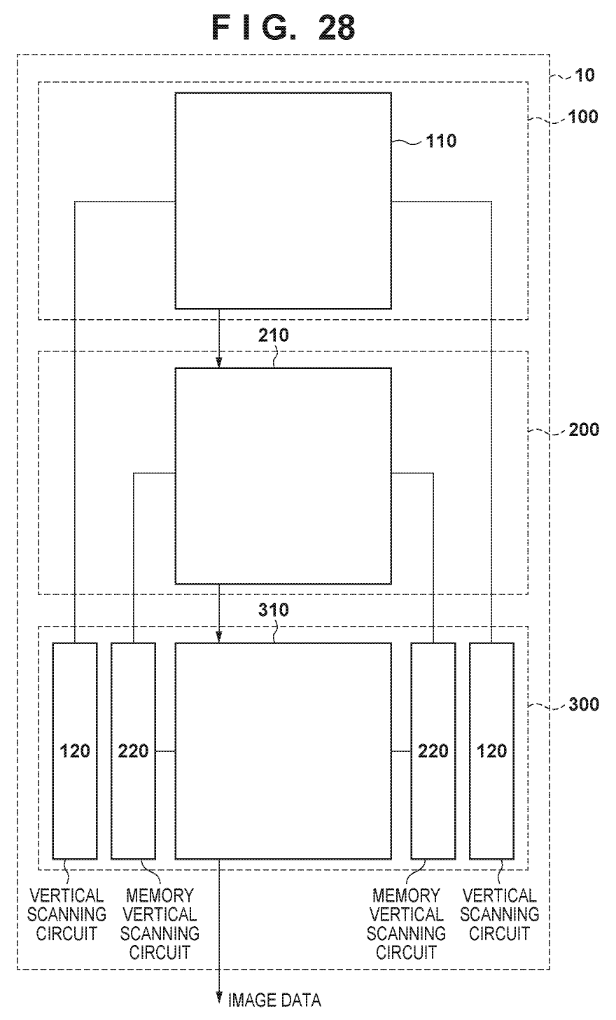

FIG. 28 is a view showing a modification of FIGS. 24 and 27, focusing on the arrangement of the vertical scanning circuit 120 and the memory vertical scanning circuit 220. As compared to FIGS. 24 and 27, the vertical scanning circuits 120 and the memory vertical scanning circuits 220 are arranged on the substrate 300. The configuration shown in FIG. 28 also shows an example in which the control signals are supplied from the left and right sides of the pixel region 110 and the memory region 210. The configuration shown in FIG. 28 can be an example in which tuning of the manufacturing process is needed not only for the substrate 100 shown in FIG. 27 but also for the substrate 200. For example, in some cases, tuning of the manufacturing process is needed to adjust the unit capacitance of the signal holding memory mem or improve the performance of the memory write transistors 213 to 215. For this reason, like FIG. 27, it may be impossible to arrange the constituent elements of the vertical scanning circuit 120 and the memory vertical scanning circuit 220 on the substrates 100 and 200, or even if they are arranged, a desired characteristic may not be obtained. In this case, like the example shown in FIG. 28, the vertical scanning circuit 120 and the memory vertical scanning circuit 220 may be arranged on the substrate 300 that is another chip to control the pixels 30 or the pixel memories 40. The vertical scanning circuits 120 and the memory vertical scanning circuits 220, which form the signal generator and are arranged on the substrate 300, generate the control signals for controlling the components arranged on the substrate 100 and the substrate 200 in the photoelectric conversion apparatus 10. In addition, the column control circuit 320 that forms the signal generator is arranged on the substrate 300, as shown in FIG. 1, to generate signals for controlling the components (for example, the column signal processing circuits 50) arranged on the substrate 300. Connection for supplying the control signals between the substrate 100 and the substrate 200 and between the substrate 200 and the substrate 300 is the same as described with reference to FIG. 27 and, for example, these may be connected via a plurality of joint portions 400 and 401.

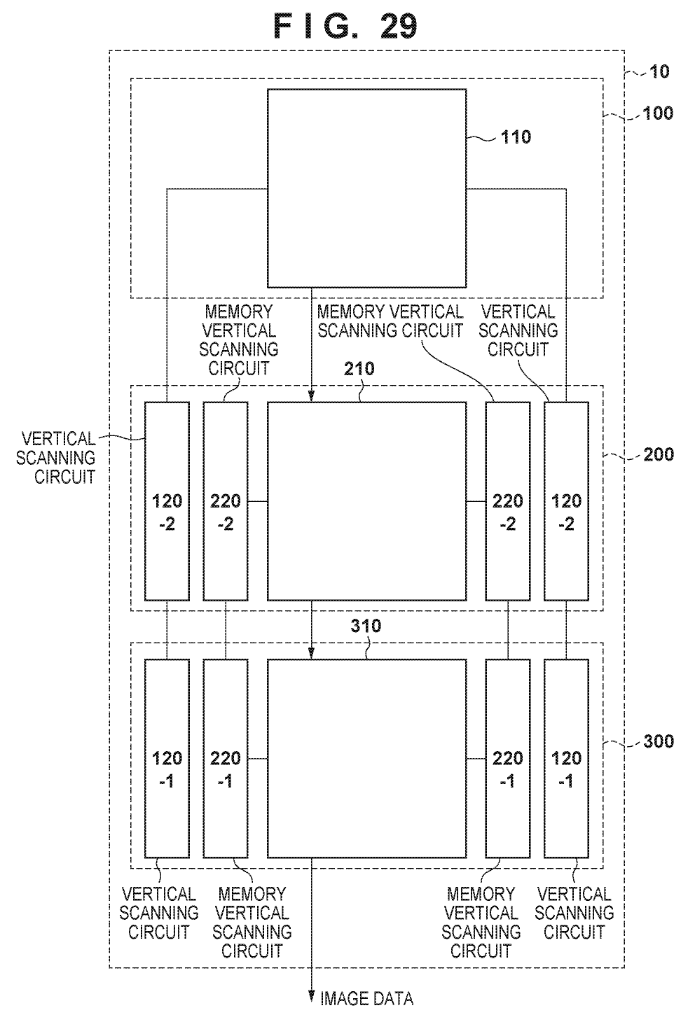

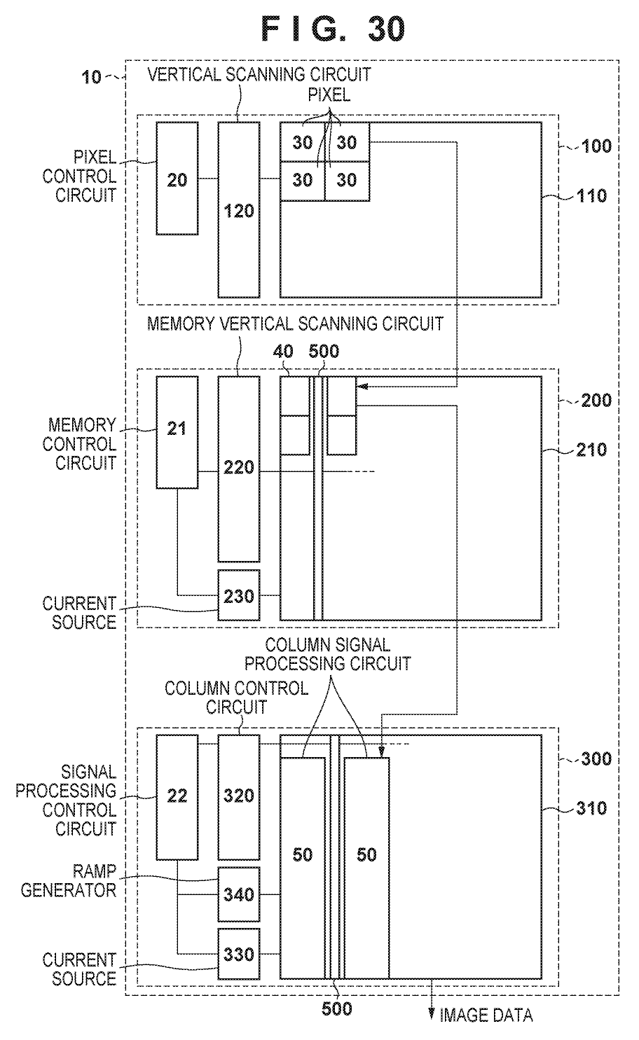

FIG. 29 is a view showing a modification of FIGS. 24, 27, and 28, focusing on the arrangement of the vertical scanning circuit 120 and the memory vertical scanning circuit 220. As compared to FIGS. 24, 27, and 28, the vertical scanning circuits 120 and the memory vertical scanning circuits 220 are distributed to the substrate 200 and the substrate 300. The configuration shown in FIG. 29 also shows an example in which the control signals are supplied from the left and right sides of the pixel region 110 and the memory region 210. As described with reference to FIGS. 27 and 28, tuning of the manufacturing process is sometimes needed for each of the substrates 100 and 200 and also the substrate 300. In this case, suitable devices may be arranged on each chip to form the vertical scanning circuits 120 and the memory vertical scanning circuits 220. For example, an arrangement for optimizing the sizes of elements forming the driver 121 and the driving force may be employed, or the arrangement may be decided based on the relationship to the reference power supplies connected to the elements forming the driver 121. Also, for example, the arrangement may be decided based on the types of transistors that can be arranged on the substrates 100, 200, and 300. For example, the arrangement may be divided according to n-type or p-type, or even if the transistors are of the same conductivity type, according to the thresholds.

FIGS. 24, and 27 to 29 show examples for explaining the arrangement of the vertical scanning circuits 120 and the memory vertical scanning circuits 220, and the photoelectric conversion apparatus 10 according to the present disclosure is not limited to the configurations of these arrangements. The combination of the arrangements of the vertical scanning circuits 120 and the memory vertical scanning circuits 220 arranged on the substrate 100, the substrate 200, and the substrate 300 may appropriately be set in accordance with the process, reference power supplies, and the types and characteristics of necessary elements. Also, it may be set in accordance with the number of pixels 30 or pixel memories 40 arranged or the area thereof. For example, even if the substrate 100 of the same size is used by not arranging the vertical scanning circuits 120 forming the signal generator on the substrate 100, like the configurations shown in FIGS. 27 to 29, a higher pixel count can be implemented. Also, for example, the vertical scanning circuits 120 may be arranged on the left and right sides to sandwich the pixel region 110, the memory region 210, or the signal processor 310 in accordance with the substrate to arrange these, and the memory vertical scanning circuits 220 may be arranged only on the left or right side. Furthermore, for example, as the drivers 121 forming the vertical scanning circuits 120 and the memory vertical scanning circuits 220, drivers 121 having different configurations described with reference to FIGS. 9 to 13 may be arranged depending on the arrangement positions of the vertical scanning circuits 120 and the memory vertical scanning circuits 220. For example, the vertical scanning circuit 120 arranged on the left side of the pixel region 110 may include the drivers 121 having the configuration shown in FIG. 9, and the vertical scanning circuit 120 arranged on the right side of the pixel region 110 may include the drivers 121 shown in FIG. 13. In this case, of the vertical scanning circuits 120, only the vertical scanning circuit 120 arranged on the left side of the pixel region 110 has the function of waveform control. Also, in the configuration shown in FIG. 29, the vertical scanning circuits 120 and the memory vertical scanning circuits 220 are distributed to the substrate 200 and the substrate 300, but these may be distributed to all the substrates 100, 200, and 300. Also, for example, the vertical scanning circuits 120 and the memory vertical scanning circuits 220 may be distributed to the substrates 100 and 300.

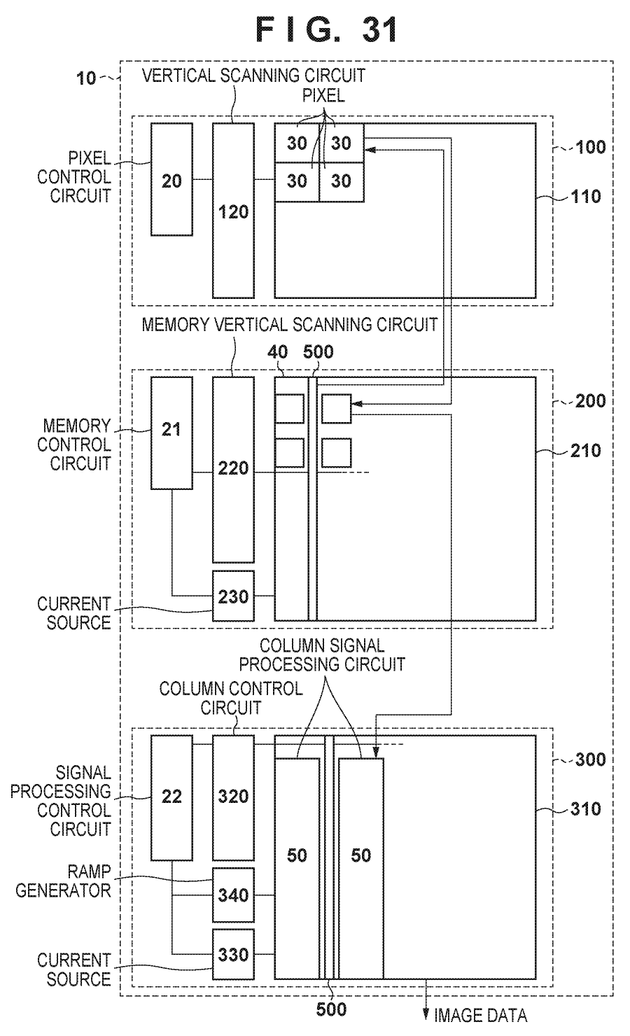

A configuration that supplies control signals output from the vertical scanning circuit 120 and the memory vertical scanning circuit 220 to the pixels 30 or the pixel memories 40 will be described next with reference to FIG. 30. FIG. 30 is a view for explaining the configuration of the photoelectric conversion apparatus 10, like FIG. 1. Unlike FIG. 1, a control signal buffer 500 is arranged in the memory region 210. To improve the sensitivity and the maximum accumulable charge amount that are the performance of a pixel, the pixel 30 is sometimes configured such that the light receiving area of the PDs 115 and 116 is maximized. In this case, the pixels 30 are arranged in an array such that adjacent pixels are densely continuously arranged. On the other hand, the pixel memory 40 need only be able to convert a charge generated in the pixel 30 into a voltage signal and hold the voltage signal and, for example, the pixel memory 40 need not be laid out with the same area as the pixel 30 if each signal holding memory mem can set a predetermined capacitance value or more. In other words, the pixel memories 40 need not comply with the size and arrangement pitch of the pixels 30.

In the configuration shown in FIG. 30, the pixel memories 40 are laid out and arrange with the shape and area different from the pixels 30, thereby arranging the control signal buffer 500 on the memory region 210. The control signal buffer 500 can be arranged, for example, between the memory write transistors 213 to 215 corresponding to the photoelectric conversion element of a pixel 30 and the memory write transistors 213 to 215 corresponding to the photoelectric conversion element of another pixel 30, which are connected to the common control signal line. When the transmission buffer for a control signal is arranged on the memory region 210, for example, the difference of the waveform of the control signal between observation points 1 to 3 of the memory region 210 described with reference to FIG. 15 can be reduced. This configuration can suppress degradation of the image quality performance caused by the difference of the transition time of falling of the control signal described with reference to FIGS. 15 to 19. The control signal buffer 500 can have the same configuration as the driver 121 described with reference to FIGS. 9 to 13 or a different configuration. Also, as for the arrangement period, the control signal buffer 500 is arranged for each column of the pixel memories 40 in the example shown in FIG. 30, but may be arranged in units of a plurality of columns. The arrangement period of the control signal buffers 500 may be changed depending on the control signal, or the pixel memories 40 may be controlled without interposing the control signal buffer 500. Furthermore, the control signal may be transmitted in series between the control signal buffers 500, that is, the output of the control signal buffer 500 of the preceding stage may be connected to the pixel memories 40 and the input of the control signal buffer 500 of the next stage. Also, for example, the control signal output from the memory vertical scanning circuit 220 may be connected to the inputs of a plurality of control signal buffers 500, and the plurality of pixel memories 40 may be controlled in parallel by the outputs of the plurality of control signal buffers 500.

The configuration shown in FIG. 30 shows an example in which the control signal buffer 500 is arranged in the region of the signal processor 310 as well. Even for the column signal processing circuits 50, the control signal buffer 500 may be arranged for each column of the column signal processing circuits 50 or at a period of a plurality of columns by adjusting the layout and the arrangement, like the pixel memories 40. In FIG. 30, the control signal buffers 500 arranged in the memory region 210 and the signal processor 310 are denoted by the same reference numerals because of their function but they may have different configurations. Like the control signal buffer 500 arranged in the memory region 210, the control signal buffer 500 arranged in the signal processor 310 may have the same configuration as the driver 121 described with reference to FIGS. 9 to 13 or may have a different configuration. The connection relationship between the control signal buffers 500 or the configuration of control to the column signal processing circuit 50 can be the same as the configuration described concerning the pixel memory 40.

FIG. 31 is a view showing, concerning the connection of the control signal buffer 500, a configuration example different from that shown in FIG. 30. As compared to FIG. 30, the memory vertical scanning circuit 220 is configured to be able to supply some of the control signals to the pixels 30. The memory vertical scanning circuit 220 may have a configuration capable of supplying all control signals to the pixels 30. As described above, depending on the layout and the arrangement of the pixels 30, it may be impossible to arrange, in the pixel region 110, a buffer corresponding to the control signal buffer 500 in the memory region 210 or the signal processor 310. In the configuration shown in FIG. 31, the control signals are supplied from the memory vertical scanning circuit 220 via the control signal buffer 500 arranged in the memory region 210, thereby controlling the pixels 30. For example, as described with reference to FIG. 22, even in the control signal of the pixel 30, the difference of the waveform of the control signal caused by the arrangement position of the pixel 30 on the pixel region 110 may affect the image quality performance. By the configuration shown in FIG. 31, the difference of the waveform between the pixels 30 can be reduced, and degradation of the image quality performance can be suppressed. On which one of the substrates 100, 200, and 300 the control signal buffer 500 is to be arranged and the constituent elements of which one of the substrates 100, 200, and 300 are to be driven are appropriately set in accordance with the restrictions of the arranged devices derived from the layout or the manufacturing process.

As described above, the transition times of rising and falling of the control signals of each transistor forming the pixel 30 or the pixel memory 40 are controlled, for example, delayed. The difference of the influence of switching noise depending on the arrangement positions of the pixels 30 in the pixel region 110 and the arrangement positions of the pixel memories 40 in the memory region 210 can thus be reduced. Also, the difference of the influence of switching noise depending on incident light, that is, the object can be reduced. It is therefore possible to implement the photoelectric conversion apparatus 10 in which degradation of image quality performance caused by the characteristic difference of switching noise is suppressed.

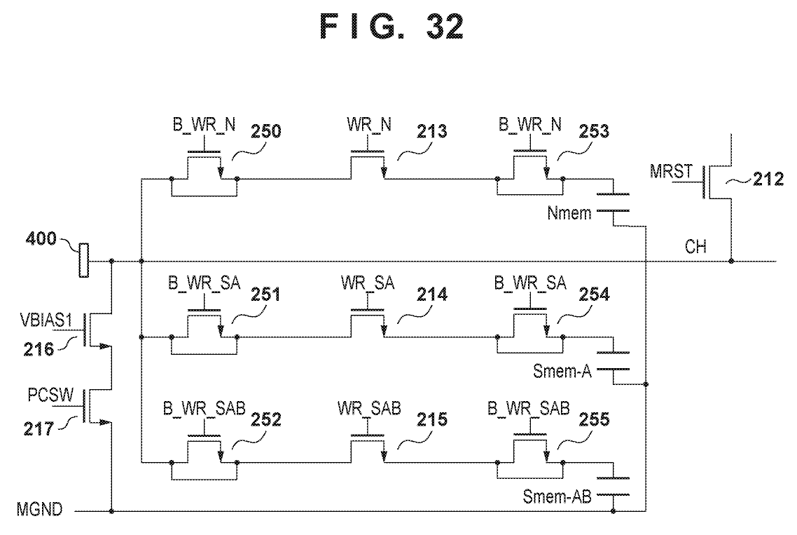

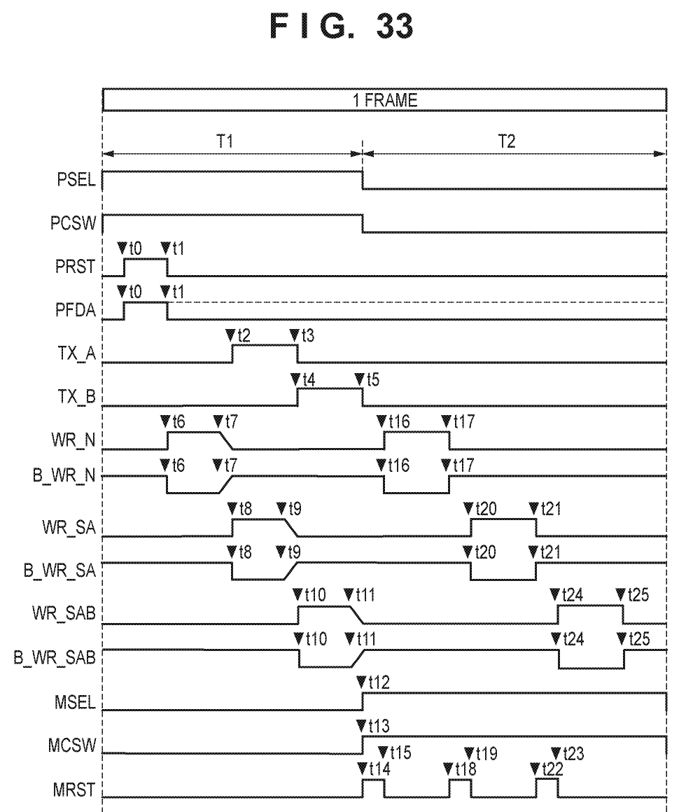

A modification of the pixel memory 40 and an operation thereof will be described next with reference to FIGS. 32 and 33. FIG. 32 is a view focusing on the memory write transistors 213 to 215 and the signal holding memories mem in the pixel memory 40 shown in FIG. 3. FIG. 32 shows the configuration between the connecting portion of the current source transistor 216 and the connecting portion of the memory reset transistor 212 to the node CH shown in FIG. 3. Differences from the configuration shown in FIG. 3 will mainly be described below.

In the pixel memory 40 shown in FIG. 32, a dummy transistor 250 is arranged between the memory write transistor 213 and the node CH, and a dummy transistor 253 is arranged between the memory write transistor 213 and the signal holding memory Nmem. Similarly, a dummy transistor 251 is arranged between the memory write transistor 214 and the node CH, and a dummy transistor 254 is arranged between the memory write transistor 214 and the signal holding memory Smem-A. Also, a dummy transistor 252 is arranged between the memory write transistor 215 and the node CH, and a dummy transistor 255 is arranged between the memory write transistor 215 and the signal holding memory Smem-AB. In each of the dummy transistors 250 to 255, the source and drain are short-circuited. Control signals B_WR_N, B_WR_SA, and B_WR_SAB are supplied to the gates of the dummy transistors 250 to 255.

FIG. 33 is a view for explaining the operation timing of the photoelectric conversion apparatus 10 including the pixel memory 40 shown in FIG. 32. As compared to the operation timing explained with reference to FIG. 14, the control signals B_WR_N, B_WR_SA, and B_WR_SAB, which are the inverted signals of the control signals WR_N, WR_SA, and WR_SAB are supplied. The dummy transistors 250 to 255 are thus controlled to perform inverted operations with respect to the memory write transistors 213 to 215.

Channel charge injection that is switching noise of the memory write transistors 213 to 215 described with reference to FIG. 15 is a phenomenon that a charge held in the channel of each transistor flows out to the source and drain of the transistor. In this embodiment, with respect to the OFF operation of the memory write transistor 213, the dummy transistors 250 and 253 perform the ON operation in terms of control. For this reason, a charge held in the channel of the memory write transistor 213 by the OFF operation of the memory write transistor 213 is absorbed by the channels of the dummy transistors 250 and 253 in accordance with the ON operation of the dummy transistors 250 and 253. That is, the influence of switching noise associated with the OFF operation of the memory write transistor 213 can be reduced by the ON operation of the dummy transistors 250 and 253. Similarly, the switching noise of the memory write transistors 214 and 215 can also be reduced by the dummy transistors 251 and 254 and the dummy transistors 252 and 255, respectively. As another switching noise, the change of the control signal sometimes causes potential variations in the signal holding memories mem or the node CH via an overlap capacitance formed between the gate and the drain of the transistor or between the gate and the source. Since the control signals of the memory write transistors 213 to 215 and the dummy transistors 250 to 255 are inverted, this acts to cancel the potential variations in the signal holding memories mem or the node CH and, therefore, the influence of the switching noise can be reduced.

The gate size of the dummy transistors 250 to 255 may be the same as that of the memory write transistors 213 to 215. For example, the charge held in the channels of the memory write transistors 213 to 215 are distributed to the sources and the drains by the OFF operation of the memory write transistors 213 to 215. Hence, the gate size of the dummy transistors 250 to 255 may be adjusted to not more than the gate size of the memory write transistors 213 to 215. For example, the gate size of the dummy transistors 250 to 255 may be 1/2 the gate size of the memory write transistors 213 to 215. In addition, the gate size may change between the dummy transistors 250 to 255. Furthermore, for example, the gate size may be adjusted (changed) between the dummy transistor 250 and the dummy transistor 253 connected to the memory write transistor 213 in accordance with the influence of switching noise. This also applies to between the dummy transistor 251 and the dummy transistor 254 and between the dummy transistor 252 and the dummy transistor 255.

FIG. 32 shows the configuration in which the dummy transistors 250 to 252 are arranged. However, the dummy transistors 250 to 252 may be disabled by fixing the control signals B_WR_N, B_WR_SA, and B_WR_SAB to high or low. Also, for example, the dummy transistors 250 to 252 may not be arranged. For example, with the drive timing shown in FIG. 33, switching noise generated by the operation of holding the voltage signals in the signal holding memories mem in the period T1 affects the signal holding memories mem and the node CH. As for the node CH, the influence of switching noise is reset by the reset operation of the node CH by the memory reset transistor 212 in the period T2. Hence, the operation and the arrangement of the dummy transistors 250 to 252 may be unnecessary. As for the arrangement of the dummy transistors 250 to 255, disabling of the operation or the presence/absence of the arrangement may be decided in accordance with the influence of switching noise, the drive timing, the layout area, and the like. Also, in this embodiment, the dummy transistors 250 to 255 are arranged for the memory write transistors 213 to 215, but other transistors may have the same configuration.

As described above, the dummy transistors 250 to 255 are arranged for the node that is affected by switching noise, and the transition time of at least one of rising and falling of the control signal is controlled, as described above. This can suppress degradation of the image quality performance caused by the characteristic difference of switching noise and implement reduction of switching noise itself, as described above.

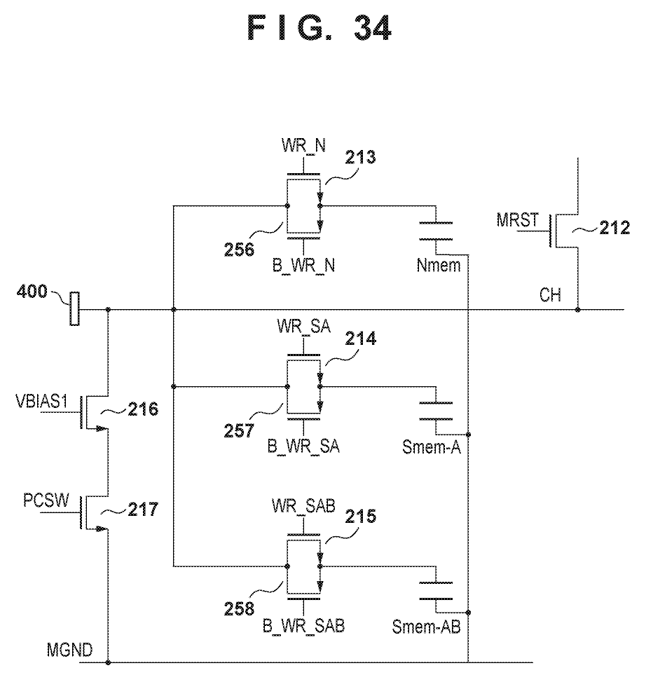

FIG. 34 is a view showing a modification of the pixel memories 40 shown in FIGS. 3 and 32. Like FIGS. 32, 34 shows the configuration between the connecting portion of the current source transistor 216 and the connecting portion of the memory reset transistor 212 to the node CH shown in FIG. 3. Differences from the configurations shown in FIGS. 3 and 32 will mainly be described below.

The pixel memory 40 shown in FIG. 34 includes, between the node CH and the signal holding memories mem, memory write transistors 256 to 258 that are p-type transistors having the conductivity type opposite to that of the n-type memory write transistors 213 to 215. The n-type memory write transistors 213 to 215 and the p-type memory write transistors 256 to 258 are arranged in parallel with respect to the signal holding memories mem. That is, the voltage signal holding operation and readout operation of each signal holding memory mem are controlled by a complementary switch formed by an n-type transistor and a p-type transistor.

The memory write transistor 213 that is an n-type transistor and the memory write transistor 256 that is a p-type transistor are arranged in parallel with respect to the signal holding memory Nmem. The control signal WR_N is supplied to the gate of the memory write transistor 213, and the control signal B_WR_N is supplied to the gate of the memory write transistor 256 that is a p-type transistor. Similarly, the memory write transistor 214 that is an n-type transistor and the memory write transistor 257 that is a p-type transistor are arranged in parallel with respect to the signal holding memory Smem-A. The control signal WR_SA is supplied to the gate of the memory write transistor 214, and the control signal B_WR_SA is supplied to the gate of the memory write transistor 257 that is a p-type transistor. Also, the memory write transistor 215 that is an n-type transistor and the memory write transistor 258 that is a p-type transistor are arranged in parallel with respect to the signal holding memory Smem-AB. The control signal WR_SAB is supplied to the gate of the memory write transistor 215, and the control signal B_WR_SAB is supplied to the gate of the memory write transistor 258 that is a p-type transistor. The drive timings of the control signals can be the same as in the operation shown in FIG. 33.

As described above, channel charge injection that is switching noise of the memory write transistors 213 to 215 is a phenomenon that a charge held in the channel of each transistor flows out to the source and drain of the transistor. As the charge held in the channel, electrons are held in an n-type transistor and holes are held in a p-type transistor, and their polarities are different. For this reason, if the n-type transistor and the p-type transistor are simultaneously turned off, the charges held in the channels of the transistors cancel each other when flowing out to the sources and drains of the transistors. That is, switching noise by the channel charge injection can be reduced. Also, as another switching noise, the change of the control signal sometimes causes potential variations in the signal holding memories mem or the node CH via an overlap capacitance formed between the gate and the drain of the transistor or between the gate and the source. Like the effect described with reference to FIGS. 32 and 33, since the control signals of the n- and p-type transistors are inverted, this acts to cancel the potential variations in the signal holding memories mem or the node CH and, therefore, the influence of the switching noise can be reduced.

As for the arrangement of the memory write transistors 213 to 215 that are n-type transistors and the memory write transistors 256 to 258 that are p-type transistors, one or both groups may be arranged in accordance with the voltage signal levels held in the signal holding memories mem. In addition, disabling of the operation of each memory write transistor or the presence/absence of the arrangement may be decided in accordance with the influence of switching noise, the drive timing, the layout area, and the like. In this embodiment, the memory write transistors have a configuration of a complementary switch, but other transistors may have the same configuration.

As described above, n- and p-type transistors are arranged in parallel with respect to the node affected by switching noise, and the transition time of at least one of rising and falling of the control signal is controlled, as described above. This can suppress degradation of the image quality performance caused by the characteristic difference of switching noise and implement reduction of switching noise itself, as described above.

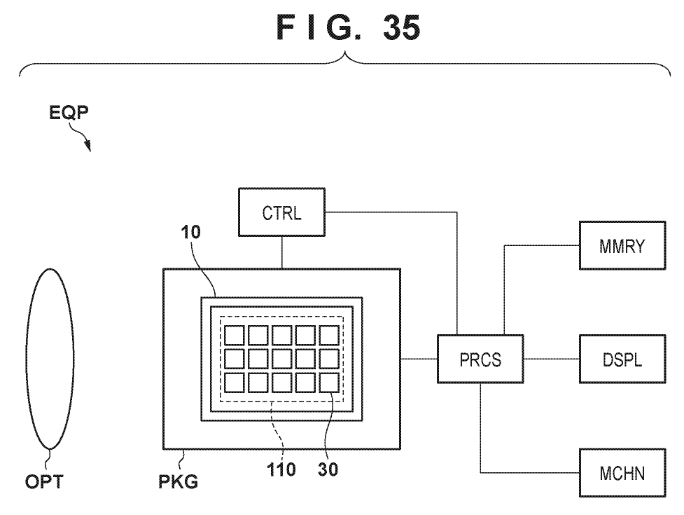

An application example of the photoelectric conversion apparatus 10 according to the above-described embodiment will be described below. FIG. 35 is a schematic view of equipment EQP including the photoelectric conversion apparatus 10. As shown in FIG. 35, the photoelectric conversion apparatus 10 is stored in a semiconductor package PKG. The package PKG can include a base to which the photoelectric conversion apparatus 10 is fixed, a lid member of glass or the like facing the photoelectric conversion apparatus 10, and a conductive connecting member such as bonding wire or bump, which connects a terminal provided on the base and a terminal provided in the photoelectric conversion apparatus 10. The equipment EQP may further include at least one of a control device CTRL, a processing device PRCS, a display device DSPL, and a memory device MMRY.

An optical system OPT forms an image on the pixels 30 arranged in the pixel region 110 of the photoelectric conversion apparatus 10, and can be, for example, a lens, a shutter, a mirror, or the like. The control device CTRL controls the operation of the photoelectric conversion apparatus 10 and can be, for example, a semiconductor device such as an ASIC. The processing device PRCS processes a signal output from the photoelectric conversion apparatus 10 and can be a semiconductor device such as a CPU or an ASIC. The display device DSPL can be an EL display device or a liquid crystal display device that displays data obtained by the photoelectric conversion apparatus 10. The memory device MMRY can be a magnetic device or a semiconductor device that stores data obtained by the photoelectric conversion apparatus 10. The memory device MMRY can be a volatile memory such as an SRAM or a DRAM, or may be a nonvolatile memory such as a flash memory or a hard disk drive. A machine device MCHN can include a movable portion or a propulsion unit such as a motor or an engine. The machine device MCHN, for example, drives a component of the optical system OPT for a zooming, focusing, or shutter operation. In the equipment EQP, data output from the photoelectric conversion apparatus 10 is displayed on the display device DSPL or transmitted to the outside by a communication device (not shown) provided in the equipment EQP. For this purpose, the equipment EQP may include the memory device MMRY or the processing device PRCS.

The equipment EQP incorporating the photoelectric conversion apparatus 10 can also be applied to a surveillance camera, or an in-vehicle camera mounted in transport equipment such as an automobile, a railway vehicle, a ship, an aircraft, or an industrial robot. In addition, the equipment EQP incorporating the photoelectric conversion apparatus 10 can be applied not only to transport equipment but also widely to equipment that uses object recognition such as an intelligent transport system (ITS).

According to the present disclosure, it is possible to provide a technique advantageous in reducing noise.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-053749, filed Mar. 27, 2025, which is hereby incorporated by reference herein in its entirety.

What is claimed is:

1. A photoelectric conversion apparatus which includes a plurality of pixels each having a photoelectric conversion element arranged therein, comprising:
a first amplification circuit configured to output, to a second node, a first signal obtained by amplifying a signal level of a first node to which a signal is supplied from the photoelectric conversion element;
a holding capacitor;
a first transistor arranged between the second node and the holding capacitor;
a second amplification circuit configured to output a second signal obtained by amplifying a signal level of the second node; and
a processing circuit configured to process the second signal,
wherein the first amplification circuit and the second amplification circuit are configured to be set in an operation state when a first control signal is at a first voltage, and to be set in a nonoperation state when the first control signal is at a second voltage,
the first transistor is configured to be set in an ON state when a second control signal is at a third voltage, and to be set in an OFF state when the second control signal is at a fourth voltage, and
the photoelectric conversion apparatus is configured to be able to operate in a driving mode in which at least one of a first transition time of the second control signal transiting from the fourth voltage to the third voltage and a second transition time of transiting from the third voltage to the fourth voltage is longer than a third transition time of the first control signal transiting between the first voltage and the second voltage.

2. The apparatus according to claim 1, wherein
the first transition time equals the second transition time.

3. The apparatus according to claim 1, wherein
the first transition time is longer than the second transition time.

4. The apparatus according to claim 1, wherein
the second transition time is longer than the first transition time.

5. The apparatus according to claim 1, wherein
the photoelectric conversion apparatus is configured to operate in the driving mode when holding the first signal in the holding capacitor.

6. The apparatus according to claim 5, wherein
at least one of the first transition time and the second transition time in the driving mode is longer than the first transition time and the second transition time when supplying a signal level of the holding capacitor to the second node.

7. The apparatus according to claim 1, wherein
the photoelectric conversion apparatus is configured to operate in the driving mode when supplying a signal level of the holding capacitor to the second node.

8. The apparatus according to claim 1, further comprising a first signal generation circuit configured to generate the second control signal,
wherein the first signal generation circuit is configured to be able to variably control the first transition time and the second transition time.

9. The apparatus according to claim 8, wherein
in the driving mode, the first signal generation circuit is configured to operate such that the second transition time when holding the first signal according to a noise level of the first node in the holding capacitor and the second transition time when holding the first signal according to a signal level supplied from the photoelectric conversion element in the holding capacitor are different.

10. The apparatus according to claim 8, wherein
each of the plurality of pixels further includes a second photoelectric conversion element different from the photoelectric conversion element, and
in the driving mode, the first signal generation circuit is configured to operate such that the second transition time when holding the first signal according to a signal level supplied from the photoelectric conversion element in the holding capacitor and the second transition time when holding the first signal according to signal levels supplied from the photoelectric conversion element and the second photoelectric conversion element in the holding capacitor are different.

11. The apparatus according to claim 8, wherein
the plurality of pixels include a first pixel and a second pixel,
the first transistor corresponding to the photoelectric conversion element of the first pixel and the first transistor corresponding to the photoelectric conversion element of the second pixel are controlled by the first signal generation circuit via a common control signal line,
a length of the control signal line from the first signal generation circuit to the first transistor corresponding to the photoelectric conversion element of the first pixel and a length of the control signal line from the first signal generation circuit to the first transistor corresponding to the photoelectric conversion element of the second pixel are different, and
in the driving mode, the first signal generation circuit is configured to generate the second control signal such that a difference between the second transition time in the first transistor corresponding to the photoelectric conversion element of the first pixel and the second transition time in the first transistor corresponding to the photoelectric conversion element of the second pixel is not more than 10%.

12. The apparatus according to claim 11, wherein
the first transistor corresponding to the photoelectric conversion element of the first pixel is, among the first transistors connected to the control signal line, a first transistor for which the length of the control signal line from the first signal generation circuit to the first transistor is shortest, and the first transistor corresponding to the photoelectric conversion element of the second pixel is, among the first transistors connected to the control signal line, a first transistor for which the length of the control signal line from the first signal generation circuit to the first transistor is longest.

13. The apparatus according to claim 1, wherein
each of the plurality of pixels further includes a second transistor arranged between the photoelectric conversion element and the first node,
the photoelectric conversion apparatus further comprises a second signal generation circuit configured to generate a third control signal for controlling the ON state and the OFF state of each second transistor, and
in the driving mode, the second signal generation circuit is configured to control such that a transition time of at least one of rising and falling between two voltages of the third control signal that switches between the ON state and the OFF state of the second transistor becomes longer than the third transition time.

14. The apparatus according to claim 1, wherein
each of the plurality of pixels further includes an additional capacitor and a third transistor arranged between the first node and the additional capacitor,
the photoelectric conversion apparatus further comprises a third signal generation circuit configured to generate a fourth control signal for controlling the ON state and the OFF state of each third transistor, and
in the driving mode, the third signal generation circuit is configured to control such that a transition time of at least one of rising and falling between two voltages of the fourth control signal that switches between the ON state and the OFF state of the third transistor becomes longer than the third transition time.

15. The apparatus according to claim 1, further comprising, between the second node and the holding capacitor, a fifth transistor configured to perform an inverted operation with respect to the first transistor.

16. A photoelectric conversion apparatus which includes a plurality of pixels each having a photoelectric conversion element arranged therein and in which a first substrate and a second substrate are stacked, comprising:
a first amplification circuit configured to output, to a second node, a first signal obtained by amplifying a signal level of a first node to which a signal is supplied from the photoelectric conversion element;
a holding capacitor;
a first transistor arranged between the second node and the holding capacitor; and
a processing circuit configured to process a second signal according to a signal level of the second node,
wherein the plurality of pixels are arranged on the first substrate, and the holding capacitor is arranged on the second substrate,
the first amplification circuit is configured to be set in an operation state when a first control signal is at a first voltage, and to be set in a nonoperation state when the first control signal is at a second voltage,
the first transistor is configured to be set in an ON state when a second control signal is at a third voltage, and to be set in an OFF state when the second control signal is at a fourth voltage, and
the photoelectric conversion apparatus is configured to be able to operate in a driving mode in which at least one of a first transition time of the second control signal transiting from the fourth voltage to the third voltage and a second transition time of transiting from the third voltage to the fourth voltage is longer than a third transition time of the first control signal transiting between the first voltage and the second voltage.

17. A photoelectric conversion apparatus which includes a plurality of pixels each including a photoelectric conversion element arranged therein, comprising:
a first amplification circuit configured to output, to a second node, a first signal obtained by amplifying a signal level of a first node to which a signal is supplied from the photoelectric conversion element;
a holding capacitor;
a first transistor arranged between the second node and the holding capacitor;
a second amplification circuit configured to output a second signal obtained by amplifying a signal level of the second node; and
a processing circuit configured to process the second signal,
wherein the first transistor is configured to be set in an ON state when a second control signal is at a third voltage, and to be set in an OFF state when the second control signal is at a fourth voltage, and
the photoelectric conversion apparatus is configured to be able to operate in a driving mode in which a first transition time of the second control signal transiting from the fourth voltage to the third voltage and a second transition time of the second control signal transiting from the third voltage to the fourth voltage are different.

18. A photoelectric conversion apparatus which includes a plurality of pixels each having a photoelectric conversion element arranged therein and in which a first substrate and a second substrate are stacked, comprising:
a first amplification circuit configured to output, to a second node, a first signal obtained by amplifying a signal level of a first node to which a signal is supplied from the photoelectric conversion element;
a holding capacitor;
a first transistor arranged between the second node and the holding capacitor; and
a processing circuit configured to process a second signal according to a signal level of the second node,
wherein the plurality of pixels are arranged on the first substrate, and the holding capacitor is arranged on the second substrate,
the first transistor is configured to be set in an ON state when a second control signal is at a third voltage, and to be set in an OFF state when the second control signal is at a fourth voltage, and
the photoelectric conversion apparatus is configured to be able to operate in a driving mode in which a first transition time of the second control signal transiting from the fourth voltage to the third voltage and a second transition time of the second control signal transiting from the third voltage to the fourth voltage are different.

19. A photoelectric conversion apparatus which includes a plurality of pixels each having a photoelectric conversion element arranged therein and in which a first substrate and a second substrate are stacked, comprising:
a first amplification circuit configured to output, to a second node, a first signal obtained by amplifying a signal level of a first node to which a signal is supplied from the photoelectric conversion element;
a holding capacitor;
a first transistor arranged between the second node and the holding capacitor; and
a processing circuit configured to process a second signal according to a signal level of the second node,
wherein the plurality of pixels are arranged on the first substrate, and the holding capacitor is arranged on the second substrate,
the first amplification circuit is configured to be set in an operation state when a first control signal is at a first voltage, and to be set in a nonoperation state when the first control signal is at a second voltage,
the first transistor is configured to be set in an ON state when a second control signal is at a third voltage, and to be set in an OFF state when the second control signal is at a fourth voltage,
the photoelectric conversion apparatus is configured to be able to operate in a driving mode in which at least one of a first transition time of the second control signal transiting from the fourth voltage to the third voltage and a second transition time of transiting from the third voltage to the fourth voltage is different from a third transition time of the first control signal transiting between the first voltage and the second voltage, and
at least a part of a signal generator including a first signal generation circuit configured to generate the first control signal and a second signal generation circuit configured to generate the second control signal is arranged on the second substrate.

20. The apparatus according to claim 19, wherein
a signal generator, of the signal generator, arranged on the second substrate is configured to generate a control signal for controlling components arranged on the first substrate and the second substrate in the photoelectric conversion apparatus.

21. The apparatus according to claim 19, wherein
a third substrate on which the processing circuit is arranged is further stacked, and the second substrate is arranged between the first substrate and the third substrate,
the signal generator further includes a third signal generation circuit configured to generate a control signal for controlling the processing circuit, and
a part of the signal generator is arranged on the third substrate.

22. The apparatus according to claim 21, wherein
a signal generator, of the signal generator, arranged on the third substrate is configured to generate a control signal for controlling components arranged on the first substrate, the second substrate, and the third substrate in the photoelectric conversion apparatus.

23. The apparatus according to claim 21, wherein
the third substrate includes a signal processor in which the plurality of processing circuits are arranged in correspondence with the photoelectric conversion elements arranged in the plurality of pixels, and
signal generators, of the signal generator, arranged on the third substrate are arranged to sandwich the signal processor.

24. The apparatus according to claim 19, wherein
the second substrate includes a memory region in which the plurality of holding capacitors are arranged in correspondence with the photoelectric conversion elements arranged in the plurality of pixels, and
signal generators, of the signal generator, arranged on the second substrate are arranged to sandwich the memory region.

25. The apparatus according to claim 19, wherein
the plurality of pixels include a first pixel and a second pixel,
the first transistor corresponding to the photoelectric conversion element of the first pixel and the first transistor corresponding to the photoelectric conversion element of the second pixel are controlled by the second signal generation circuit via a common first control signal line, and
on the first control signal line, a buffer is arranged between the first transistor corresponding to the photoelectric conversion element of the first pixel and the first transistor corresponding to the photoelectric conversion element of the second pixel.

26. The apparatus according to claim 19, wherein
the signal generator simultaneously drives and controls the plurality of pixels, simultaneously drives and controls the plurality of first transistors corresponding to the photoelectric conversion elements arranged in the plurality of pixels, and simultaneously drives and controls the plurality of processing circuits corresponding to the photoelectric conversion elements arranged in the plurality of pixels.

27. Equipment comprising:
the photoelectric conversion apparatus according to claim 1; and
a processing device configured to process a signal output from the photoelectric conversion apparatus.

28. Equipment comprising:
the photoelectric conversion apparatus according to claim 16; and
a processing device configured to process a signal output from the photoelectric conversion apparatus.

29. Equipment comprising:
the photoelectric conversion apparatus according to claim 17; and
a processing device configured to process a signal output from the photoelectric conversion apparatus.

30. Equipment comprising:
the photoelectric conversion apparatus according to claim 18; and
a processing device configured to process a signal output from the photoelectric conversion apparatus.

31. Equipment comprising:
the photoelectric conversion apparatus according to claim 19; and
a processing device configured to process a signal output from the photoelectric conversion apparatus.
